(19) United States
(12) Patent Application Publication
(10) Pub. No.: US 2008/0181337 A1
(43) Pub. Date: Jul. 31, 2008

(54) Spur and Distortion Management Techniques for an RF Receiver

(75) Inventor: Adrian Maxim, Austin, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: SILICON LABORATORIES, INC., Austin, TX (US)

(21) Appl. No.: 11/755,135

(22) Filed: May 30, 2007

Related U.S. Application Data
(63) Continuation-in-part of application No. 11/669,762, filed on Jan. 31, 2007.

(51) Int. Cl. H04L 27/00; G06F 3/033; H03M 1/66

(52) U.S. Cl. 375/340; 341/144; 455/130; 455/230

(57) ABSTRACT

A receiver (1800) includes a mixing digital-to-analog converter (DAC) (1807), a direct digital frequency synthesizer (DDFS) (1848), a first power detector (1826), and a first control circuit (1834). The mixing DAC (1807) receives a digital local oscillator (LO) signal and a radio frequency (RF) signal and provides an output signal located in a first frequency band. The DDFS (1848) includes a first clock input that is configured to receive a first clock signal that sets a sample rate for the digital LO signal. The first power detector (1826) has an input coupled to an output of a switching section (1808) of the mixing DAC (1807). An output of the first power detector (1826) is configured to provide a channel power associated with the output signal. The first control circuit (1834) is coupled to the output of the first power detector (1826) and is configured to identify blockers based on the channel power associated with the output signal and select a frequency of the first clock signal to reduce multiplicative spur frequency translation of the blockers into the first frequency band when a desired channel is selected.

This application is a continuation-in-part of U.S. patent application Ser. No. 11/669,762, filed Jan. 31, 2007, entitled “SPUR REJECTION TECHNIQUES FOR AN RF RECEIVER,” the disclosure of which is hereby incorporated herein by reference in its entirety for all purposes.

### FIELD OF THE DISCLOSURE

The present disclosure is generally directed to a radio frequency (RF) receiver and, more particularly, to spur and distortion management techniques for an RF receiver.

### BACKGROUND

Reducing spurs in radio frequency (RF) receiver designs can be a relatively challenging task. Moreover, adequately addressing spur rejection in the design of broadband RF receivers that implement a direct digital frequency synthesizer (DDFS) in combination with a mixing digital-to-analog converter (DAC) may be particularly challenging. This is due to, at least in part, the fact that RF receivers that employ mixing DACs usually implement a relatively high frequency clock signal, e.g., 3 GHz, to generate digital local oscillator (LO) signals for the receivers. In such RF receivers, the mixing DAC has included an RF transconductance section and a switching section. The RF transconductance section has included an input that received an RF signal and an output that provided an RF current signal. The switching section has been coupled to the RF transconductance section and has included inputs that received bits associated with the digital LO signal, which has been provided at outputs of a direct digital frequency synthesizer (DDFS) based on a single high frequency clock signal.

The switching section has mixed the RF current signal with the digital LO signal to provide an analog output signal at an output of the switching section. The single high frequency clock signal has set a sample rate for the digital LO signal, which has been based on a sampled sine wave. Unfortunately, RF receivers that employ a single high frequency clock signal to set a sample rate for a DDFS provided digital LO signal may have spur issues at combinations of the clock signal frequency and the LO signal frequency, as well as multiples thereof.

What is need is a technique for managing spurs in an RF receiver that implements a direct digital frequency synthesizer (DDFS) in combination with a mixing digital-to-analog converter (DAC).

### SUMMARY

According to one embodiment, a receiver includes a mixing digital-to-analog converter (DAC), a direct digital frequency synthesizer (DDFS), and a first power detector. The mixing DAC includes a radio frequency (RF) transconductance section and a switching section. The RF transconductance section includes an input configured to receive an RF input signal and an output configured to provide an RF current signal. The switching section is coupled to the RF transconductance section and includes inputs configured to receive bits associated with a digital local oscillator (LO) signal and an output. The switching section is configured to mix the RF current signal with the digital LO signal to provide an output signal, which is located in a first frequency band, at the output of the switching section. The DDFS includes outputs configured to provide the bits associated with the digital LO signal and has a first clock input configured to receive a first clock signal that sets a sample rate for the digital LO signal. The first power detector includes an input coupled to an output of the switching section and an output that is configured to provide a channel power associated with the output signal. The first control circuit is coupled to the output of the first power detector and is configured to identify blockers based on the channel power associated with the output signal and select a frequency of the first clock signal to reduce multiplicative spur frequency translation of the blockers into the first frequency band when a desired channel is selected.

According to another embodiment, a receiver includes a mixing digital-to-analog converter (DAC), a direct digital frequency synthesizer (DDFS), and a first power detector. The mixing DAC includes a radio frequency (RF) transconductance section and a switching section. The RF transconductance section includes an input configured to receive an RF input signal and an output configured to provide an RF current signal. The switching section is coupled to the RF transconductance section and includes inputs configured to receive bits associated with a digital local oscillator (LO) signal and an output. The switching section is configured to mix the RF current signal with the digital LO signal to provide an output signal, which is located in a first frequency band, at the output of the switching section. The DDFS includes outputs configured to provide the bits associated with the digital LO signal and has a first clock input configured to receive a first clock signal that sets a sample rate for the digital LO signal. The first power detector includes a power input, an output and a control input. The power input of the first power detector is coupled to the input of the RF transconductance section. The first control circuit is coupled to the output of the first power detector and is configured to adjust a level of a control signal provided to the control input of the first power detector, based on whether blockers are located at sensitive distortion positions when a desired channel is selected. The first control circuit is also configured to cause the RF input signal to be attenuated when RF power detected by the first power detector exceeds a power level set by the control signal provided to the control input of the first power detector.

According to another aspect, a method of improving reception of a receiver includes identifying one or more blockers associated with a desired channel (included in a radio frequency (RF) input signal) based on a channel power associated with an output signal (which is located in a first frequency band) of the receiver. A frequency of a clock signal (which sets a sample rate for a direct digital frequency synthesizer (DDFS)) is selected to reduce multiplicative spur frequency translation of the one or more blockers into the first frequency band when a digital local oscillator (LO) signal (provided by the DDFS) is mixed with the RF input signal.

According to yet another aspect, a method of improving reception of a hybrid receiver includes determining whether a received channel, included within a radio frequency (RF) input signal of the hybrid receiver, is an analog channel or a digital channel. A first automatic gain control (AGC) loop power detector trip point of a first AGC loop (associated with an RF path of the hybrid receiver) is set to a first level when the received channel is an analog channel. The first AGC loop power detector trip point is set to a second level, which is lower in magnitude than the first level, when the received channel is a digital channel.

### BRIEF DESCRIPTION OF THE DRAWINGS

The present disclosure may be better understood, and its numerous features and advantages made apparent to those skilled in the art by referencing the accompanying drawings, in which:

FIG. 1 is an electrical diagram, in block and schematic form, of a relevant portion of a radio frequency (RF) receiver that implements a mixing digital-to-analog converter (DAC), configured according to an embodiment of the present invention;

FIG. 2. is an electrical diagram, in block and schematic form, of a relevant portion of an RF receiver whose phase locked loop (PLL) is configured to provide a variable frequency clock signal (f_{DDFS}) responsive to control of an input divider and a feedback divider to reduce spurs in the RF receiver, according to an embodiment of the present invention;

FIG. 3 is an electrical block diagram of a relevant portion of an RF receiver that is configured to switch between high-side and low-side mixing to reduce spurs in the RF receiver, according to an embodiment of the present invention;

FIG. 4 is an electrical diagram, in block and schematic form, illustrating spur coupling between an aggressor magnetic loop and a victim magnetic loop that may be present within an RF receiver;

FIG. 5 is an electrical diagram, in block and schematic form, illustrating use of a series-shunt regulator to power a direct digital frequency synthesizer (DDFS) employed within an RF receiver, according to an embodiment of the present invention;

FIG. 6 is an electrical diagram, in block and schematic form, of the diagram of FIG. 5 in further detail, according to an embodiment of the present invention;

FIG. 7 is an electrical diagram, in block and schematic form, illustrating the effect of quality factor on spur coupling between an aggressor magnetic loop and a victim magnetic loop that may be present within an RF receiver;

FIG. 8 is an electrical diagram, in block and schematic form, illustrating the use of capacitors, according to an embodiment of the present invention, to modify resonance frequencies of an aggressor magnetic loop and a victim magnetic loop both of which may be present within an RF receiver;

FIG. 9 is an electrical block diagram, in block and schematic form, illustrating the use of a capacitor to modify a resonance frequency of victim magnetic loops that share a power supply and which may be present within an RF receiver;

FIG. 10 is a top level view of an integrated circuit (IC) that is configured, according to an embodiment of the present invention, to reduce spur coupling between a digital aggressor circuit and an analog victim circuit both of which may be present within an RF receiver;

FIG. 11 is a cross-sectional view of the IC of FIG. 10;

FIG. 12 is an electrical diagram, in block and schematic form, illustrating potential coupling points for deep N-type wells associated with an aggressor magnetic loop and a victim magnetic loop of the IC of FIGS. 10 and 11, according to an embodiment of the present invention;

FIG. 13 is a flow chart of an example process for switching between high-side and low-side mixing to improve spur rejection of the RF receiver of FIG. 3;

FIG. 14 is an example spur landscape diagram for an RF receiver that plots a number of spurs (represented by diagonal lines) versus local oscillator (LO) frequency (f_{LO}) and indicates blocker positions for an LO frequency of 720 MHz and a DDFS frequency (f_{DDFS}) of 3.072 GHz;

FIG. 15 is a diagram indicating magnitudes of multiplicative spurs, associated with the blockers of FIG. 14, that fall within an intermediate frequency (IF) band of the RF receiver;

FIG. 16 is an example spur landscape diagram for an RF receiver that plots a number of spurs (represented by diagonal lines) versus LO frequency and indicates blocker positions for an LO frequency of 720 MHz and a DDFS frequency of 2.967 GHz;

FIG. 17 is a diagram indicating magnitudes of multiplicative spurs, associated with the blockers of FIG. 16, that fall outside an IF band of the RF receiver;

FIG. 18 is an electrical block diagram of an RF receiver that implements a multiplicative spur frequency management technique to reduce spurs within an IF band;

FIG. 19 is a flow chart of an example multiplicative spur frequency management technique for reducing spurs within an IF band;

FIG. 20 is an electrical block diagram of an RF receiver that implements adjustable automatic gain control (AGC) trip points for an RF power detector and an IF power detector based on information stored within a memory of the RF receiver;

FIG. 21 is an electrical block diagram of an RF receiver that implements adjustable AGC trip points for an RF power detector based on distortion measurements;

FIG. 22 is an electrical block diagram of an RF receiver that implements two AGC loops;

FIG. 23 is an electrical block diagram of an RF receiver that implements three AGC loops;

FIG. 24 is an electrical block diagram of an RF receiver that implements analog sensing of analog/digital channels; and

FIG. 25 is an electrical block diagram of an RF receiver that implements digital sensing of analog/digital channels.

The use of the same reference symbols in different drawings indicates similar or identical items.

### DETAILED DESCRIPTION

As noted above, reducing spurs in radio frequency (RF) receiver designs can be a relatively challenging task. As is also noted above, adequately addressing spur rejection in the design of broadband RF receivers (e.g., terrestrial/cable TV receivers) that implement a direct digital frequency synthesizer (DDFS) in combination with a mixing digital-to-analog converter (DAC) may be particularly challenging. In general, RF signal independent spurs may have frequencies at +/−N*f_{DDFS}+/−P*f_{LO}, where f_{DDFS} is a DDFS clock signal frequency and f_{LO} is a local oscillator (LO) signal frequency provided by the DDFS. As is typical, the LO signal is used to tune the RF receiver to a desired channel. In general, spurs may be attributed to power supply modulation of switching section (mixer) glitch energy or an LO modulated glitch due to finite output impedance of an RF transconductance section current path leg. In a typical RF receiver employing a mixing DAC, switching pairs (Gilbert cells) of the switching section of the mixing DAC switch in a local oscillator (LO) dependent fashion and, therefore, at the mixing DAC output there may be a relatively large LO impulse energy, due to the Cdv/dt current injection through parasitic capacitances associated with the switching pairs.

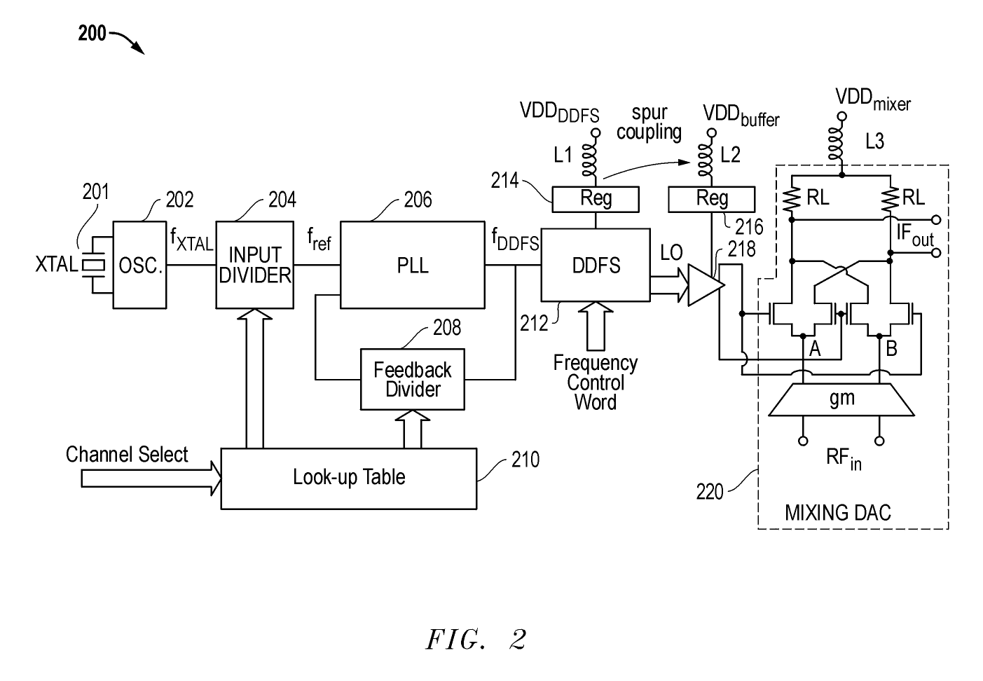

The current injected into an intermediate frequency (IF) path of the RF receiver may also depend on the final slewing value of a control signal provided by LO buffers. Due to the finite power supply rejection ratio (PSRR) at an associated power supply regulator, a large amount of the DDFS supply current impulse energy (at the DDFS clock signal frequency) may be coupled to the LO path and modulate the final value of the mixer control voltage. As such, at the output of the mixing DAC, a parasitic mixing effect may occur which multiplies the P*f_{LO} glitch energy by the N*f_{DDFS} supply injected tone. At common source points (see FIG. 2, points ‘A’ and ‘B’) of the switching pairs, the frequency appears doubled due to the rectification process that appears at the common mode points of a fully differential circuit. As such, at these common mode points, a relatively strong even order LO harmonic, e.g., 2f_{LO}, 4f_{LO}, etc., exists.

The finite output impedance of the current path leg at these high frequencies result in a tail current at 2f_{LO}, 4f_{LO}, etc. Moreover, switching of the switching pairs at the DDFS clock signal frequency, which is required to generate a sampled LO sine wave, results in switching at the DDFS clock signal frequency of the 2Q*f_{LO} tail current component. Unfortunately, this results in spurs at +/−N*f_{DDFS}+/−2Q*f_{LO}. In general, the spurs given by the two spur mechanisms that are relatively far outside the IF band are not usually important. That is, the amplitude of signals relatively far outside the IF band are strongly attenuated by the finite bandwidth of the IF path and, therefore, a down-conversion in the IF path, due to the non-linearity of the IF blocks, does not occur. However, the N*f_{DDFS}−P*f_{LO} and the P*f_{LO}−N*f_{DDFS} spurs may fall inside the IF band. In general, these spurs are independent of the amplitude of the RF signal and can significantly desensitize a tuner. Assuming the first spur mechanism (i.e., power supply modulation of switching section glitch energy) can be rejected by using a relatively high PSSR for the power supply regulators, the second spur mechanism (i.e., LO modulated glitch due to finite output impedance of the RF transconductance section current path leg) is still intrinsic to the mixing DAC architecture. The output impedance of the current path leg is limited by parasitic device capacitance which generally cannot be reduced further, assuming the layout is performed in a relatively compact manner with low layout capacitance.

For a given desired (selected) channel (f_{desired}) and a given TV standard, an IF (f_{IF}) and an LO frequency (f_{LO}) are fixed. In such a case, the spur impact on the receiver sensitivity can be avoided if the spur frequency+/−N*f_{DDFS}+/−P*f_{LO} falls outside the 6 MHz or 8 MHz IF path band. According to various aspects of the present invention, spurs are moved out of the IF band by adjusting the DDFS clock signal frequency. While the discussion herein is primarily applicable to moving spurs out of the IF band, it is contemplated that the techniques disclosed herein are directed to moving spurs out of other bands, e.g., a baseband. In a DDFS based local oscillator (LO) synthesizer, a frequency of an LO signal is not directly dependent on a frequency of a DDFS clock signal. However, the frequency of the LO signal is dependent on the DDFS accumulator setting. As such, even if the frequency of the DDFS clock signal is changed there exists a different accumulator setting that provides approximately the same LO signal frequency. In practice, a TV demodulator can usually handle a +/−100 kHz LO frequency error. Assuming a large enough DDFS accumulator size, it is possible to move a parasitic spur by +/−5 MHz, or more, such that the parasitic spur falls out of the IF band.

According to various aspects of the present invention, a frequency management technique is disclosed herein that modifies a direct digital frequency synthesizer (DDFS) clock frequency by manipulating one or more dividers associated with a phase locked loop (PLL) in an attempt to move signal independent spurs outside an intermediate frequency (IF) signal band of a radio frequency (RF) receiver. According to another frequency management technique, a complex RF receiver may be switched between high-side and low-side mixing to avoid or minimize both signal dependent (i.e., image signals) and signal independent spurs. According to this technique, a power of an image frequency is measured using both high-side mixing and low-side mixing. Then, an appropriate one of the high-side or low-side mixing is selected based upon which of the high-side and low-side mixing has a lower image frequency power.

A number of different circuit techniques may also be employed to improve the spur rejection of a complex RF receiver. According to one or more techniques, a configuration of digital block and analog block power supply regulators may be selected to improve spur rejection. Additionally, design techniques may be employed to avoid resonance frequencies in the power supply circuits. As used herein, a “radio frequency” signal means an electrical signal conveying useful information and having a frequency from about 3 kilohertz (kHz) to thousands of gigahertz (GHz), regardless of the medium through which such signal is conveyed. Thus, an RF signal may be transmitted through air, free space, coaxial cable, fiber optic cable, etc. As used herein, the term “coupled” includes both a direct electrical connection between elements (or blocks) and an indirect electrical connection between elements (or blocks) provided by one or more intervening elements (or blocks).

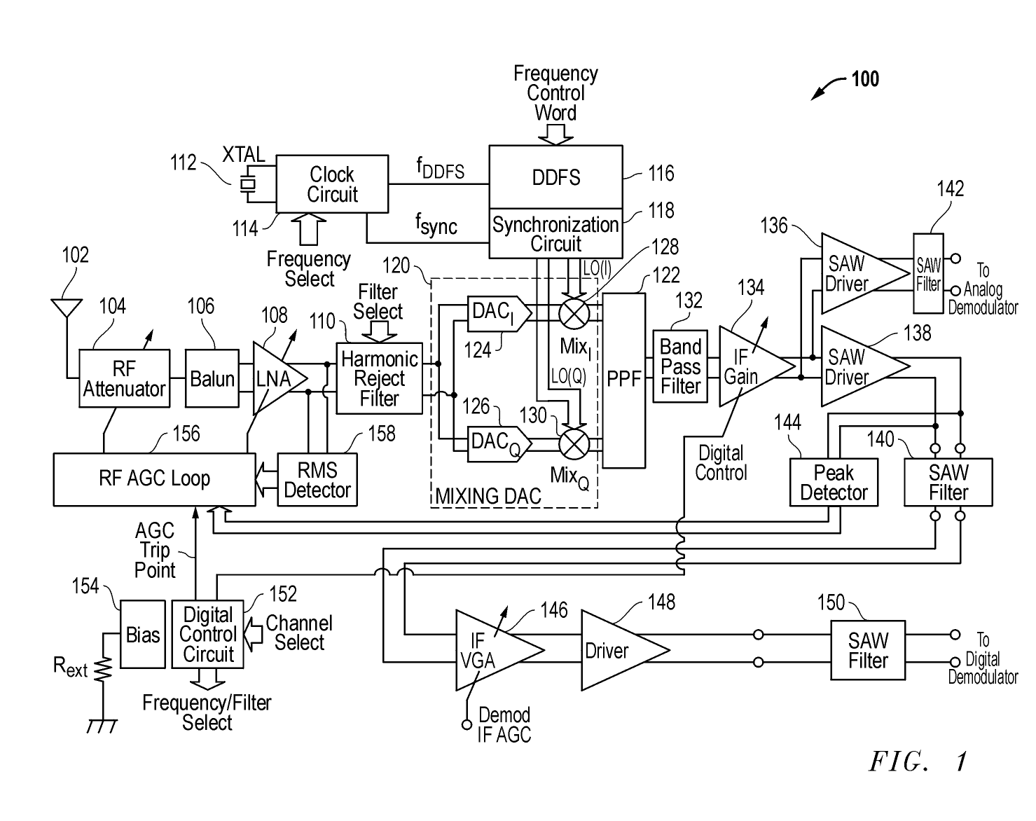

With reference to FIG. 1, an exemplary hybrid terrestrial/cable analog/digital television (TV) receiver (tuner) 100 is illustrated. The receiver 100 implements a direct digital frequency synthesizer (DDFS) 116 that drives a mixing digital-to-analog converter (DAC) 120, via a synchronization circuit 118, with a digital local oscillator (LO) signal. The synchronization circuit 118, which may include a master-slave latch structure and buffers, ensures that bits associated with quadrature LO signals (i.e., LO(I) and LO(Q)) arrive at respective inputs of the mixing DAC 120 at substantially similar arrival times. A clock circuit 114, which includes a phase locked loop (PLL), provides a DDFS clock signal (f_{DDFS}) to the DDFS 116 and a synchronization clock signal (f_{sync}) to the synchronization circuit 118. As is depicted, the receiver 100 includes an RF attenuator 104 that receives a TV signal from an antenna 102. An attenuation provided by the attenuator 104 is controlled by an RF automatic gain control (AGC) loop 156 such that strong incoming signals are adequately attenuated to avoid non-linearities (e.g., clipping) in an RF front-end, which includes low noise amplifier (LNA) 108 and the mixing DAC 120, etc. In general, the attenuator 104 should have a relatively low insertion loss such that it does not significantly impact noise figure performance of the receiver 100. The RF attenuator 104 may be implemented using, for example, an off-chip pin diode.

An output of the RF attenuator 104 is coupled to an input of a balun 106, which converts a signal at the output of the RF attenuator 104 into a differential signal, which is provided to a differential input of the LNA 108. In general, the balun 106 should have a relatively low insertion loss and a relatively good output amplitude and phase matching in order to minimize common mode to differential coupled noise/spur conversion at the input of the receiver 100. A 1 to N, e.g., a 1 to 2, balun can be used to provide gain in the signal path and, thus, reduce a noise contribution of active circuits in the receiver 100. While a balun cannot provide power gain, i.e., it is a passive circuit, a balun can provide an impedance value change, e.g., from 75 Ohms to 300 Ohms in a 1 to 2 balun. By changing the reference impedance level, the noise figure of the receiver 100 may be improved.

The LNA 108 may be configured to have a programmable gain in discrete steps that is set by the RF AGC loop 156. In general, the LNA 108 should be designed to ensure good matching to the balun 106 output impedance. Outputs of the LNA 108 are respectively coupled to inputs of a programmable harmonic reject filter 110, which is configured to improve harmonic rejection performance of the receiver 100. At lower channel frequencies, e.g., in the VHF band, a low-pass filter may be employed to increase the blocker rejection of the LO harmonic frequencies, e.g., 2f_{LO}, 3f_{LO}, 4f_{LO}, etc. At higher channel frequencies, e.g., in the UHF band, a high-pass filter may be employed to reject harmonic distortion components generated by the LNA 108. When no harmonic issues exist, the filter 110 may be switched to an all-pass filter, such that the filter 110 does not degrade the noise figure performance of the receiver 100. It should be appreciated that the filter 110 may be realized as either a passive or an active filter. In general, passive filters have lower noise, but also exhibit lower harmonic rejection. In contrast, active filters provide a higher harmonic rejection, but generally exhibit larger noise contribution.

Outputs of the filter 110 are coupled to respective inputs of the mixing DAC 120, which in this case includes a pair of quadrature mixing DACs. The mixing DACs 120 each have two main sub-blocks, i.e., RF transconductance sections 124 and 126 and switching sections (mixers) 128 and 130. The RF transconductance sections may be configured as, for example, RF transconductance DACs. The RF transconductance sections 124 and 126 convert an RF input voltage into an RF current, based on a value of each local oscillator (LO) bit provided by the DDFS 116. In general, a segmented DAC architecture offers a good power/performance compromise. Alternatively, a full binary encoded DAC or a full thermometer encoded DAC may be utilized. Typically, a full binary encoded DAC consumes lower power, but also exhibits lower linearity. In contrast, a full thermometer encoded DAC usually has higher linearity, but also requires higher power. In a typical application, the mixers 128 and 130 are configured as an array of switching pairs (Gilbert cells) that perform the mixing operation on a bit-by-bit basis. The mixer LO path includes a digital bus that provides a digital encoding, e.g., binary, thermometer, or segmented, of an instantaneous LO sampled sine wave to inputs of the mixers 128 and 130.

In general, the harmonic rejection of a mixing DAC depends both on the linearity of the RF transconductance section and on synchronization of DDFS control bit arrival times at the LO inputs of the mixers. As mentioned above, the outputs of the DDFS 116 are provided to inputs of the synchronization circuit 118. The DDFS 116 is driven by a first clock signal and the synchronization circuit 118 is driven by a second clock signal. The first and second clock signals may or may not have the same frequency, depending on whether the DDFS 116 is built as a single core or includes multiple cores. In general, the DDFS clock signal (f_{DDFS}) is less important in terms of phase noise and spurs since the LO data is synchronized later in the LO path. However, the second clock signal (f_{sync}) usually should have relatively low phase noise and low spurs, as the second clock signal determines the receiver phase noise and may impact the blocking performance of the receiver 100. The outputs of the mixers (MIX₁ and MIX_{Q}) 128 and 130 are provided to a poly-phase filter (PPF) 122, e.g., a fifth-order PPF, that ensures a relatively high value image rejection level over a relatively wide intermediate frequency (IF) range that covers, for example, multiple TV standards, e.g., 33 MHz to 60 MHZ for Europe, USA, and Asian compliant TV receivers. The PPF 122 also performs complex-to-real conversion of the IF signal.

Outputs of the PPF 122 are coupled to respective inputs of bandpass filter 132. The bandpass filter 132 is implemented in the IF path in order to improve blocking performance of the receiver 100 and to lessen (or avoid) detection of blocker power by peak detector 144. The bandpass filter 132 may be implemented using a tuned active stage having an on-chip capacitance and an off-chip inductance that may be selected based on the TV standard. Outputs of the bandpass filter 132 are coupled to respective inputs of a programmable gain amplifier (PGA) 134 that sets the receiver 100 IF gain at a desired value based on the application, e.g., cable or terrestrial TV. As is depicted, an analog receiver path includes a surface acoustic wave (SAW) driver 136 that drives an off-chip SAW filter 142, whose output is coupled to an analog demodulator (not shown). An amplitude of a signal at the output of the SAW driver 136 should generally be at least about 3 mV to ensure proper operation of an IF AGC loop. A digital receiver path includes a SAW driver 138 that drives an off-chip SAW filter 140, whose output is coupled to an input of an IF variable gain amplifier (VGA) 146. An output of the VGA 146 is coupled to an input of a driver 148, whose output is coupled to an input of an off-chip SAW filter 150, whose output is coupled to an input of a digital demodulator (not shown). To reduce the cost of the receiver 100, the SAW filter 150 may be omitted and, in this case, the driver 148 would directly drive the digital demodulator.

In a typical analog/digital RF receiver, a digital demodulator does not include a built-in IF AGC variable gain amplifier (VGA). Thus, for digital TV applications, an additional 50 to 65 decibel (dB) gain is usually required, depending on SAW filter insertion loss, to provide a desired amplitude at an analog-to-digital converter (ADC) input of the digital demodulator. In this embodiment, the VGA 146 is employed to provide a desired gain and gain range. To avoid clipping of the signals at the RF front-end and at an output of IF path SAW driver 138, a dual RF/IF AGC loop may be implemented. In this case, a gain of both the RF attenuator 104 and the LNA 108 are set by the RF AGC loop 156, based on a power level sensed by an RF root mean square (RMS) detector 158 and peak signal level sensed by the peak detector 144 (at the SAW driver 138 output). A variable AGC trip point may be set via a digital control circuit (digital interface) 152, which also sets the gain in the IF path and control parameters for the clock circuit 114 and the DDFS 116. A bias circuit 154 may be employed that utilizes a high precision external resistor (Rₑₓₜ) to accurately set bias current and voltage levels required for proper operation of the receiver 100.

With reference to FIG. 2, a relevant portion of an RF receiver 200 is depicted that is configured, according to an embodiment of the present invention, to employ a frequency management technique to reduce spurs. As is shown, the receiver 200 includes a crystal (XTAL) 201 that is coupled to an input of crystal oscillator 202, whose output is coupled to a first input of a programmable input divider 204. An output of the divider 204 is coupled to a first input of a phase locked loop (PLL) 206, whose output is coupled to a clock input of a direct digital frequency synthesizer (DDFS) 212. A programmable feedback divider 208 is coupled between the output of the PLL 206 and a second input of the PLL 206. In operation, the PLL 206 provides a channel appropriate DDFS clock signal to the clock input of the DDFS 212. A frequency of the DDFS clock signal is equal to f_{XTAL}*(feedback divider/input divider), where f_{XTAL} corresponds to a reference frequency provided by the crystal oscillator 202.

In general, the goal is to shift a frequency of the DDFS clock signal such that spurs at +/−N*f_{DDFS}+/−P*f_{LO} fall out of the IF band (e.g., centered at 44 MHz and having a 6 MHz bandwidth) for a selected channel. Typically, this can be achieved by selecting proper values for the input divider 204 and the feedback divider 208 from a look-up table 210, based on a selected channel. As is shown, the look-up table 210 receives a channel select signal and outputs respective control signals to inputs of the dividers 204 and 208. Outputs of the DDFS 212 are coupled to control inputs of switching section (switching pairs) of a mixing digital-to-analog converter (DAC) 220, via buffers 218 (only one of which is shown). A synchronization circuit (not shown in FIG. 2) may also be employed between the DDFS 212 and the buffers 218 to ensure that bits associated with an LO signal, provided by the DDFS 212, arrive at the control inputs of the switching section of the mixing DAC 220 at substantially the same time. The DDFS 212 is coupled to a first power supply (VDD_{DDFS}) via a bond-wire (L1) and a power supply regulator 214 (e.g., a series-shunt regulator). Similarly, the buffers 218 are coupled to a second power supply (VDD_{buffer}) via a bond-wire (L2) and a power supply regulator 216 (e.g., a series regulator) and the mixing DAC 220 is coupled to a third power supply (VDDₘᵢₓₑᵣ) via a bond-wire (L3).

It should be appreciated that different spurs move at different speeds, given by +/−N*f_{DDFS}+/−P*f_{LO}. For example, for N equal to 1, for each MHz frequency shift of the DDFS clock signal, the spurs also move by 1 MHz. As another example, for N equal to 2, for each MHz frequency shift of the DDFS clock signal, the spurs move by 2 MHz. In general, spurs move by N MHz for each MHz of frequency change in the DDFS clock signal. As there may be several sets of spurs moving at different speeds and in both positive and negative directions (based on the +/−N*f_{DDFS} sign) at an output of a mixing DAC, it is possible that while one spur may be moved out of the IF band another spur may be moved into the IF band.

To reduce the occurrence of this event, a DDFS clock signal frequency shifting increment of a relatively small value may be desirable. Usually, having a 2 MHz or 4 MHz frequency increment is suitable to move all spurs out-of-band. Typically, a voltage control oscillator (VCO) of a PLL needs to have a relatively wide tuning range to accommodate the frequency management technique. Since the +/−N*f_{DDFS}+/−P*f_{LO} spurs have a predetermined position, the TV spectrum may be characterized for the discrete LO frequencies required by terrestrial/cable applications and a look-up table may be implemented, e.g., in hardware. In this case, the look-up table provides a PLL clock frequency for each LO signal frequency to ensure that all spurs are moved out of the IF band. That is, for each LO setting the look-up table provides appropriate settings for the input and feedback dividers 204 and 208 to achieve a desired frequency for the DDFS clock signal. In the event that the DDFS implements multiple DDFS cores that operate at 1/S of a desired frequency, additional spurs may also appear in the form of +/−N*f_{DDFS}/S+/−P*f_{LO}, where S is the number of DDFS cores. In general, if a relatively large number of spurs exist, a smaller frequency increment and a wider PLL tuning range are required to ensure that all spurs fall out of the IF band.

Another solution to avoid fixed frequency signal independent spurs is to switch between high-side and low-side mixing, as the LO frequencies required for high-side and low-side mixing are different and one of the LO frequencies is likely to move the +/−N*f_{DDFS}+/−P*f_{LO} spurs out of the IF band. In this case, DDFS clock signal frequency is kept constant (at a high-side or a low-side frequency) and high-side mixing or low-side mixing is employed, depending on whether high-side mixing or low-side mixing has less spur issues. In general, the difference between the two LO frequencies is 2f_{IF} which results in a 2*P*f_{IF} shift of the spur frequency. In general, in a receiver including a DDFS driven mixing DAC, it is relatively simple to switch between high-side and low-side complex mixing by implementing a multiplexer between the DDFS and the mixing DAC. The multiplexer is used to direct a cosine to in-phase (I) inputs and a sine to quadrature (Q) inputs of the mixing DAC for high-side mixing and the sine to the I inputs and the cosine to Q inputs of the mixing DAC for low-side mixing. It should be appreciated that the value of a DDFS register is also required to be changed to set an LO signal to an appropriate frequency.

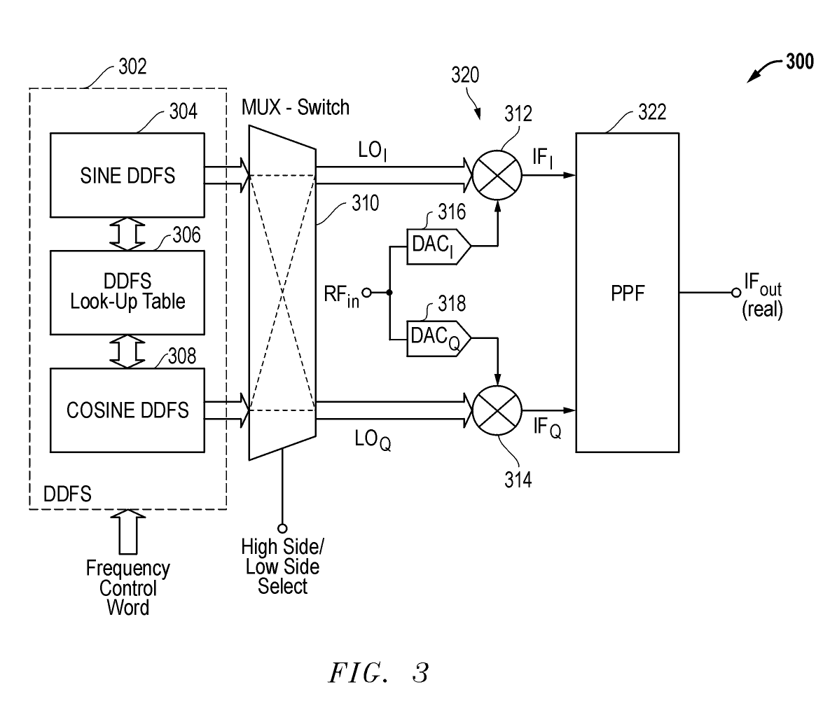

With reference to FIG. 3, a relevant portion of a complex RF receiver 300 is depicted that is configured to switch between high-side and low-side mixing. The receiver 300 includes a direct digital frequency synthesizer (DDFS) 302 that includes a DDFS look-up table 306 that, responsive to a frequency control word, provides appropriate sampled values for sine or cosine waveforms. The look-up table 306 is coupled to a sine DDFS block 304 and to a cosine DDFS block 308. The sine DDFS block 304 provides digital bits that correspond to a sine LO signal and the cosine DDFS block 308 provides digital bits that correspond to a cosine LO signal. The sine and cosine LO signals are provided to respective inputs of a multiplexer 310, whose first outputs are coupled to control inputs of a switching section (mixer) 312 and whose second outputs are coupled to control inputs of a switching section (mixer) 314. The mixers 312 and 314 are included within a mixing DAC 320, which also includes RF transconductance sections 316 and 318. When high-side mixing is selected, the cosine LO signal is routed to control inputs of the mixer 312 and the sine LO signal is routed to control inputs of the mixer 314. When low-side mixing is selected, the sine LO signal is routed to control inputs of the mixer 314 and the cosine LO signal is routed to control inputs of the mixer 312. Outputs of the mixer 312 are coupled to first inputs of the poly-phase filter (PPF) 322 and outputs of the mixer 314 are coupled to second inputs of the PPF 322.

Typically, digital demodulators of an analog/digital RF receiver can process both a high-side and a low-side mixed signal. Normally, the difference between the two situations is an image of the frequency spectrum. However, analog demodulators of analog/digital RF receivers can generally only handle high-side mixing. In the analog demodulator case, the DDFS clock signal frequency management technique may be employed to address spur issues. Another draw back of the high-side/low-side mixing swap is that the frequency shift, i.e., 2*P*f_{IF}, is rather coarse and while moving one spur out of the IF band the approach may move another spur into the IF band. However, employing the high-side/low-side mixing technique may be particularly advantageous when spurs are signal dependent. As the terrestrial TV spectrum is not that densely populated, in most cases, if a blocking channel is present at an image frequency for high-side injection it is generally not present at an image frequency for low-side injection, due to the relatively large separation between the image frequencies for the two modes. For example, assuming high-side mixing in a receiver that employs an intermediate frequency f_{IF} of 44 MHz and having a desired channel frequency (f_{desired}) centered at 100 MHz, a local oscillator frequency f_{LO} of 144 MHz would be employed and an image frequency f_{image} would be located at 188 MHz. For low-side mixing in a receiver that employs an intermediate frequency f_{IF} of 44 MHz and having a desired channel frequency (f_{desired}) centered at 100 MHz, a local oscillator frequency f_{LO} of 56 MHz would be employed and an image frequency f_{image} would be located at 12 MHz.

According to various embodiments of the present invention, and with reference to FIG. 13, a process 1300 for implementing a high-side/low-side mixing technique is depicted. In block 1302, a receiver receives a command to tune to a selected channel (f_{desired}). In a typical case, the receiver may first be configured to receive an image frequency of the selected channel in a high-side mode. In this case, at block 1304, an output power at an image frequency (f_{imH}) is determined for the high-side mode. The receiver is then configured to receive an image frequency of the selected channel in a low-side mode. In block 1306, an output power at an image frequency (f_{imL}) is determined for the low-side mode. Next, in decision block 1310, the receiver determines whether the image power in the high-side mode is less than the image power in the low-side mode. If the image power is lower in the high-side mode, control transfers from block 1310 to block 1312, where high-side mixing is employed. If the image power is higher in the high-side mode, control transfers from block 1310 to block 1314, where low-side mixing is employed. Following blocks 1312 or 1314, control transfers to block 1316 where the channel is received in the selected mode. In this manner, a signal-to-noise ratio (SNR) degradation, due to finite image rejection, may be reduced.

In a typical mixed-signal integrated circuit (IC) broadband RF receiver, e.g., a system on a chip (SOC), that employs a mixing digital-to-analog (DAC) based architecture, the largest amount of digital noise/spurious tones is usually generated by a direct digital frequency synthesizer (DDFS) that drives the mixing DAC. As such, achieving a low spur level RF receiver requires good isolation of digital blocks (e.g., the DDFS) from analog blocks (e.g., the analog front-end and other analog components). In general, the lowest RF receiver power dissipation can be achieved by using a minimal digital power supply voltage with no regulation or filtering. However, if the DDFS impulse power supply current, e.g., the current attributable to the switching of the digital gates and flip-flops, is allowed to flow through a power supply bond-wire, an off-chip external bypass capacitor and return on-chip through a ground bond-wire, then a relatively large magnetic loop may exist that strongly couples spurs to a magnetic loop that contains analog front-end power supply bond-wires.

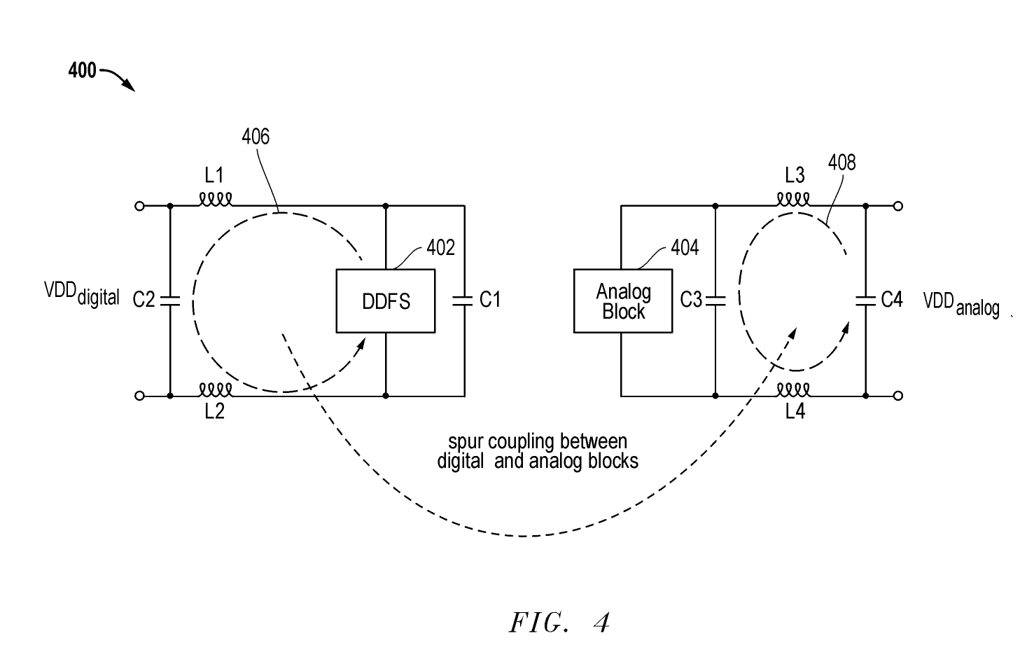

With reference to FIG. 4, an electrical diagram 400 illustrates spur coupling between a DDFS 402 and an analog circuit (block) 404, e.g., an analog RF front-end. As is illustrated, an aggressor magnetic loop 406 is formed by the DDFS 402, power supply (VDD_{digital}) bond-wires L1 and L2, and off-chip bypass capacitor C2. Similarly, a victim magnetic loop 408 is formed by power supply (VDD_{analog}) bond-wires L3 and L4, off-chip bypass capacitor C4, and on on-chip bypass capacitor C3.

Due to finite power supply rejection ratio (PSRR) and common mode to differential gain of the analog RF front-end, digital coupled spurs may end up in the RF signal path and desensitize the receiver. In general, improving a forward PSRR of regulators that are used to bias the RF front-end and improving matching in the differential stages of the RF front-end does not reduce spur levels below a desired noise floor level. The RF front-end cannot usually implement an arbitrarily large device size to provide low common mode to differential gain, due to parasitic capacitance (associated with large device sizes) that limits signal path bandwidth. In general, spur coupling may be reduced by minimizing an area of a victim magnetic loop. Moreover, spur coupling from the aggressor magnetic loop can be reduced by: increasing a distance between aggressor and victim magnetic loops; ensuring 90 degree, or as close as possible, orientation between the aggressor and victim magnetic loops; reducing the area of the aggressor magnetic loop; and reducing the amount of impulse current going through the aggressor magnetic loop.

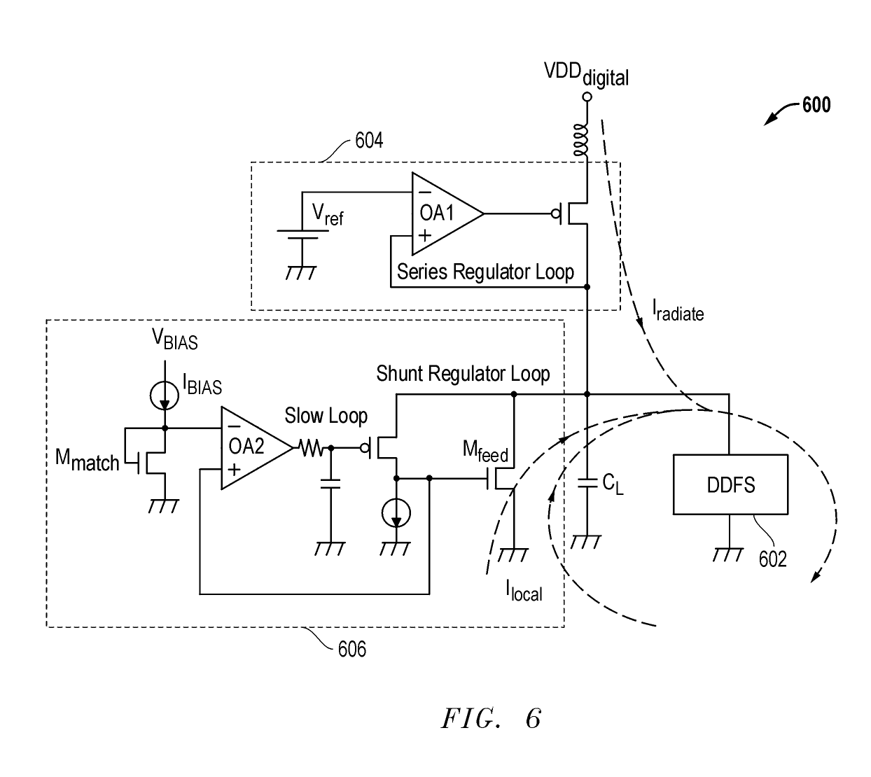

Typically, employing a standard series regulator for a digital load does not substantially reduce the amount of impulse current flowing through a power supply bond-wire, as an output impedance of the series regulator is generally lower than a reactance of an on-chip load capacitance (C_{L}) placed across the digital load (e.g., a DDFS) up to moderately high frequencies. To minimize the amount of impulse power supply current that flows through a power supply bond-wire, a parallel (shunt) regulator may be implemented. If all devices are in normal active state, then an impedance (an output impedance of a DC bias current source (I_{BIAS})) looking toward the power supply bond-wire is relatively large. In this case, the DDFS impulse current is substantially maintained on-chip and, as such, a smaller loop results that has relatively low radiation. Moreover, a high frequency load current component flows through the load capacitance C_{L} and a medium frequency load current component flows through a local feedback loop that includes a transistor M_{FEED} (see FIG. 6).

During proper operation of a shunt power supply regulator (shunt regulator), a DC bias current is provided that is higher than a highest instantaneous load current. When the load current is smaller than the DC bias current, the excess DC bias current flows through a shunt loop including the transistor M_{FEED}. Unfortunately, the shunt regulator has relatively poor power efficiency as DC bias current is wasted in the shunt loop when the load current is smaller than a peak load current. Typically, DDFS cores operating at multi-GHz frequencies require relatively large power supply currents, e.g., several hundreds of milliamperes on the average and up to several amperes of peak current. As such, shunt regulators alone are usually impractical in RF receivers that employ a DDFS in conjunction with a mixing DAC.

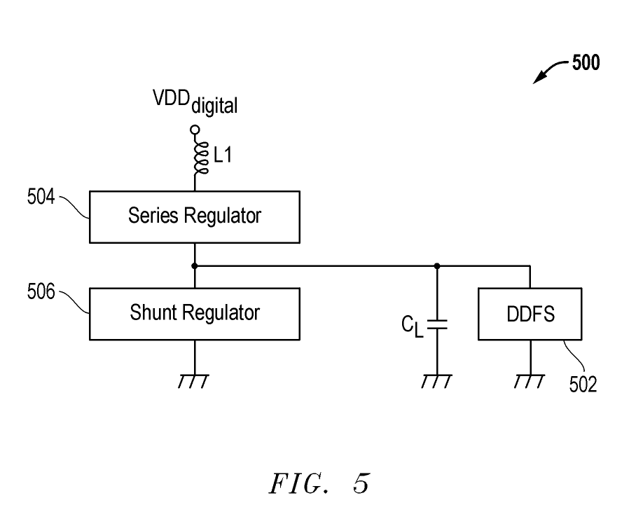

Turning to FIG. 5, a hybrid power supply regulator (i.e., a series-shunt power supply regulator) 500 is employed to power a direct digital frequency synthesizer (DDFS) 502. In this architecture, a main DC current for the DDFS 502 is provided by a series regulator 504, while high frequency impulse current is provided by a shunt regulator 506 and its parallel bypass capacitor C_{L}. An advantage of using the series regulator 504 is that the series regulator 504, as contrasted with a shunt regulator, provides a required DC bias current for the DDFS 502 without wasting current. At high frequencies, the shunt regulator 506 and the load capacitor C_{L} offer a low impedance locally to the digital impulse current, which essentially prevents the digital impulse current from flowing through supply bond-wire L1.

Moving to FIG. 6, a hybrid series-shunt regulator 600 is illustrated that includes a series regulator 604 and a shunt regulator 606 that are employed to power a DDFS 602, while reducing the ability of the DDFS 602 to radiate spurs. In general, the higher the bandwidth of the shunt regulator 606 loop, the more current is carried by transistor M_{FEED}. It should, however, be appreciated that achieving a high bandwidth requires a high transconductance and, thus, usually requires a relatively large current consumption in the shunt regulator 606. A good compromise between power and reverse PSRR may be achieved by using 1/10 or ⅕ of the total DDFS DC current in the shunt loop. Typically, using a relatively large value load capacitance C_{L} improves the reverse PSRR at medium and high frequencies. Employing a series-shunt regulator allows a reverse PSRR of 40 to 60 decibel (dB) to be achieved. However, in many broadband receiver applications, e.g., a terrestrial TV receiver, an overall PSRR of −75 to −85 dB is desirable. In this case, using a series-shunt regulator, by itself, to isolate a DDFS from the analog blocks of the receiver is not usually sufficient. To increase the PSRR, additional regulators with high forward PSSR may be implemented to power various analog blocks. The combination of the reverse PSRR at the series-shunt regulator and the forward PSRR at the front-end circuitry bias regulators can usually provide spur levels of −75 to −85 dBc (decibel with respect to the carrier).

In general, to improve the isolation between digital and analog circuits, the digital and analog circuits should implement separate power supply lines. However, as previously discussed, magnetic coupling may occur between the different power supply circuits. In general, power supply bond-wire inductances and, on-chip and off-chip bypass capacitors constitute a poorly damped inductor-capacitor (LC) circuit that has a relatively large quality factor (Q). When the frequency of operation is relatively far from the LC resonance frequency, the current circulating in the aggressor magnetic loop is relatively small. However, if the aggressor circuit frequency is close to or at the LC circuit resonance frequency, then the current in the aggressor magnetic loop is boosted by the quality factor (Q) value, which is typically in the range of 10 to 50. Thus, even if a small amount of current is injected in the aggressor magnetic loop, the injected current can generate a relatively large coupling effect in the victim magnetic loop. To address this situation, an on-chip bypass capacitor may be employed to modify the resonance frequency of the aggressor magnetic loop.

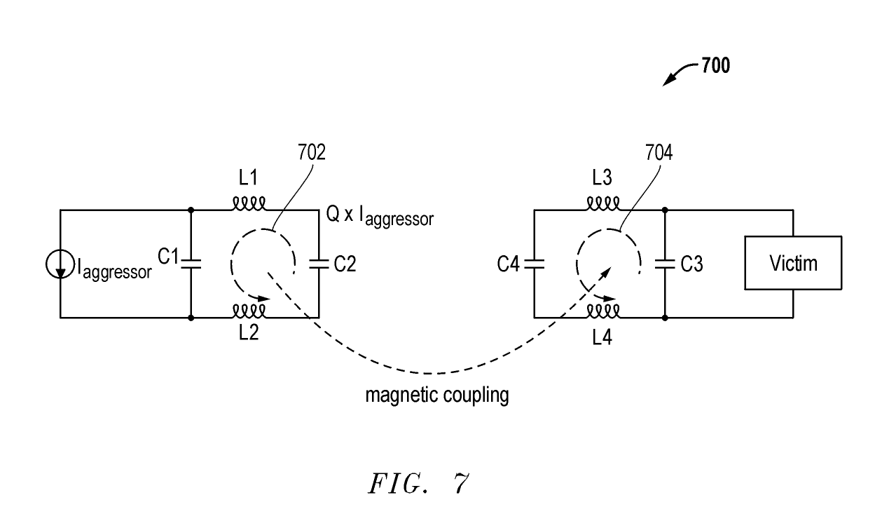

With reference to FIG. 7, a circuit diagram 700 illustrates magnetic coupling between an aggressor magnetic loop 702 and a victim magnetic loop 704 and the effect of resonance on magnetic coupling between the loops 702 and 704. The victim magnetic loop 704 is formed by an off-chip capacitor C4, an on-chip capacitor C3, and bond-wires L3 and L4. The aggressor magnetic loop 702 is formed by on-chip capacitor C1, off-chip capacitor C2, and bond-wires L1 and L2. As is depicted, a current (I_{aggressor}) that flows through the aggressor magnetic loop 702 is multiplied by a quality factor (Q) of the LC circuit that forms the aggressor magnetic loop 702. To reduce the current in the aggressor magnetic loop 702, the value of the on-chip capacitor C1 is selected to modify the resonance frequency of the aggressor magnetic loop 702 to a frequency that is relatively far from a DDFS frequency.

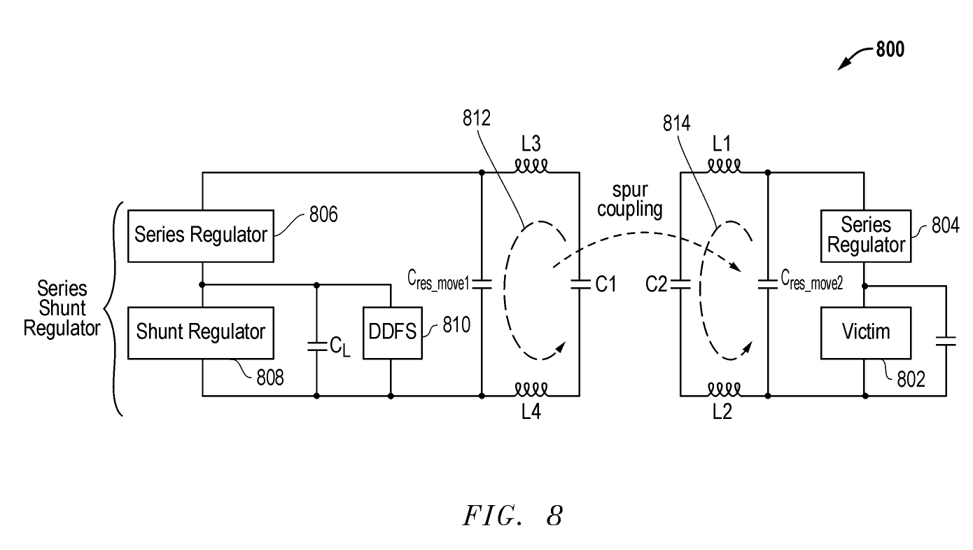

With reference to FIG. 8, a circuit diagram 800 illustrates coupling between an aggressor magnetic loop 812 and a victim magnetic loop 814 and the use of added on-chip bypass capacitors (Cres_move1 and Cres_move2) to move a resonance frequency of the aggressor and victim magnetic loops 812 and 814, respectively, to reduce coupling. As is shown, an aggressor circuit includes a DDFS 810 that receives power via a series regulator 806 and a shunt regulator 808. A load capacitor C_{L} is positioned to filter power delivered, via the regulators 806 and 808, to the DDFS 810. A victim circuit 802 receives power via a series regulator 804. The aggressor magnetic loop 812 is provided by the on-chip capacitor Cres_move1, an off-chip capacitor C1, and bond-wires L3 and L4. The victim magnetic loop 814 is provided by the on-chip capacitor Cres_move2, an off-chip capacitor C2, and bond-wires L1 and L2.

A value of the on-chip bypass capacitor Cres_move1 should usually be selected to ensure that the resonance frequency is either lower or higher than the spectrum of induction for the DDFS 810. However, in DDFSs that operate at multi-GHz frequencies it may be relatively difficult to move the resonance frequency higher, due to the finite on-chip bypass capacitance that exists intrinsically in the circuit. In this case, one solution is to move the resonance frequency lower to avoid current boosting in the aggressor magnetic loop 812. A similar situation exists in the victim side where the power supply circuit has a poorly damped LC circuit with a given resonance frequency. As noted above, the victim resonance frequency may be moved out of the aggressor frequency range by adding a sufficient value on-chip bypass capacitor Cres_move2.

In addition to the DDFS coupled spurs, the analog front-end may produce spurs that should not be coupled to other analog circuits. For example, in a mixing DAC based receiver, the mixer LO path buffers and synchronization latches have parasitic spurs at f_{LO}, f_{DDFS}, f_{DDFS}+/−f_{LO}, 2f_{DDFS}+/−f_{LO}, etc. In general, the worst resonance frequency to deal with is at f_{DDFS}, where a substantial amount of energy usually exists. In parallel DDFS architectures, f_{DDFS}/S is of interest, where S is the number of DDFS cores in parallel. In various applications, e.g., terrestrial/cable TV, the minimum frequency of interest is around 40 MHz. In general, it is not possible to move the LC resonance frequency of the power supply lines lower than the lowest channel of interest by using a reasonable capacitor value for an on-chip bypass capacitor. In this case, one solution is to add enough capacitance to move the resonance frequency far from the major spurious tone frequencies, e.g., f_{DDFS} and f_{DDFS}/S. Typically, a few hundred MHz resonance frequency shift may be realized with capacitances having a value of hundreds of picofarads. Assuming the resonance is still in the TV band, current boosting still occurs. When channels still experience spur problems, a frequency management technique, such as swapping high-side and low-side mixing, may be employed. In general, the combination of moving the power supply current resonance frequency and the avoidance of the LO channels that create the spurs around the resonance frequency provides a receiver that has relatively low spur coupling.

Usually, minimizing the cost of an RF receiver requires minimizing the number of pins of an integrated circuit (IC) package of the receiver. The requirement of a low number of package pins typically prevents the implementation of separate power supply pins for each IC block. As such, in any given design, several blocks typically share the same supply pins. According to various aspects of the present invention, some of the blocks may use a regulator and some of the blocks may be directly coupled to power supply lines. In a standard regulator design, a filter capacitor C_{L} is connected in parallel with a load. The capacitance that appears on a power supply line magnetic loop includes a parasitic capacitance of a power supply regulator. This parasitic capacitance, in general, is poorly controlled over process, temperature, and supply corners. Moreover, in the case of multiple power supply regulators that have a common power supply, the sum of the parasitic capacitances of all the power supply regulators should be considered. At typical bond-wire inductance values and device parasitic capacitance values, the resonance frequency of a receiver implementing a multi-regulator architecture is in the GHz range and, therefore, spurs may fall on the f_{DDFS} or f_{DDFS}/S frequencies.

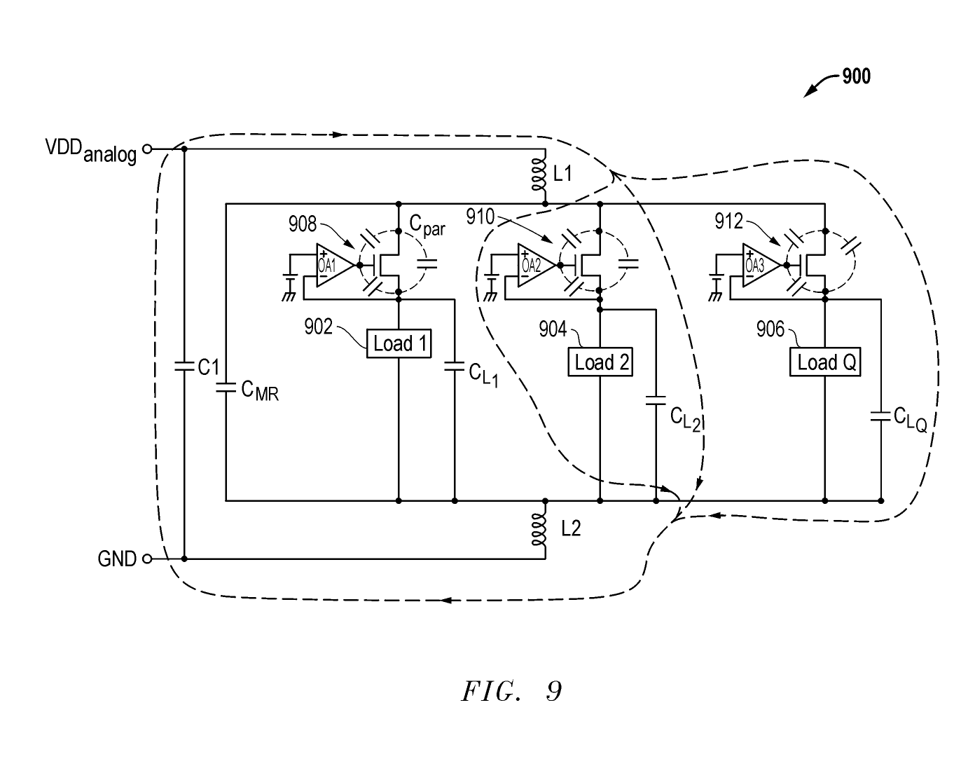

With reference to FIG. 9, a circuit 900 is illustrated that includes three analog circuits (loads) that share the same power supply. Loads 902, 904, and 906, each utilize separate series regulators 908, 910, and 912, respectively. To address the potential spur problem created in the circuit 900, a relatively large value capacitor C_{MR} may be placed directly between the power supply VDD_{analog} lines to move the resonance frequency to a lower frequency. As disclosed above, spur boosting at the resonance frequency may be addressed by using various frequency management techniques.

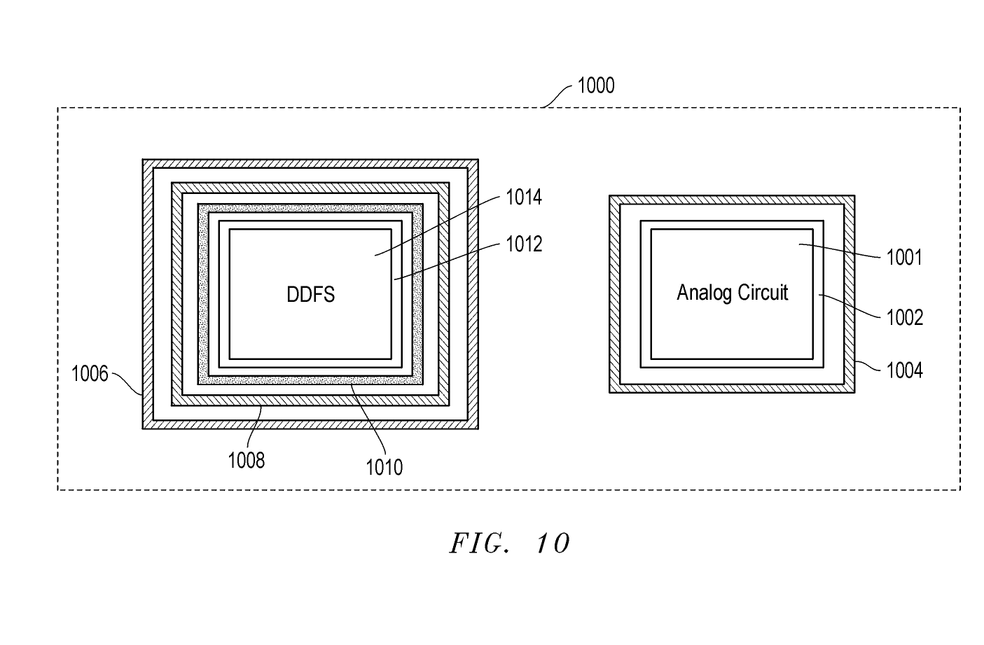

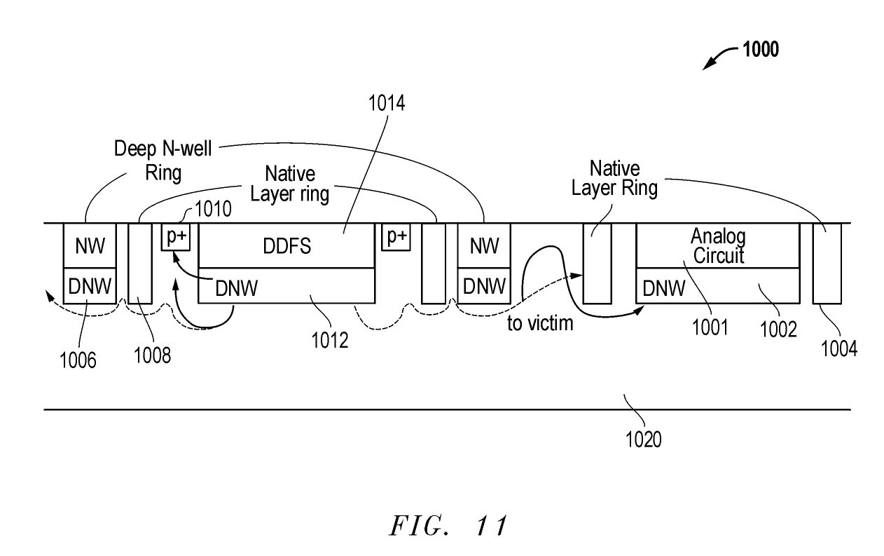

Another concern in large mixed-signal system on chips (SOCs) is substrate spur coupling between digital and analog circuits (blocks). In such an SOC, digital and analog blocks are realized on the same die, i.e., substrate, and, as such, there is a finite amount of coupling between the different blocks through the substrate. FIGS. 10 and 11 depict an SOC 1000 that includes a DDFS 1014 that is formed in associated P-type and N-type wells (not shown) that are formed in a first deep N-type well (DNW) 1012 and an analog circuit 1001 that is formed in associated P-type and N-type wells (not shown) that are formed in a second deep N-type well (DNW) 1002. In a typical case, both the DDFS 1014 and the analog circuit 1001 utilize complementary metal-oxide semiconductor (CMOS) circuits. While placing digital and analog circuits in separate deep N-type wells provides relatively good isolation at low frequencies, at high frequencies (where most spur energy exists), a parasitic capacitance of a deep N-type well may provide a short which reduces an isolation level between the digital and analog blocks.

In a typical receiver, a digital block is generally relatively large as compared to analog blocks and, as such, a parasitic capacitance of the digital block is relatively large. To minimize coupling between the digital and analog blocks, the deep N-type well of an analog block may be made as small as possible to reduce parasitic capacitance. However, in receivers that achieve image and harmonic rejection natively, i.e., with no analog or digital correction or calibration, analog circuits need to have a relatively large area to provide the required matching. For example, a mixing DAC needs to have a relatively large area to ensure high DAC linearity and, thus, good harmonic and image rejection. In this case, additional guard rings may be employed around the digital block (aggressor) and the analog blocks (victims) to improve isolation. For example, additional guard rings 1008 and 1004 may be employed around the DDFS 1014 and the analog circuit 1001 to improve isolation.

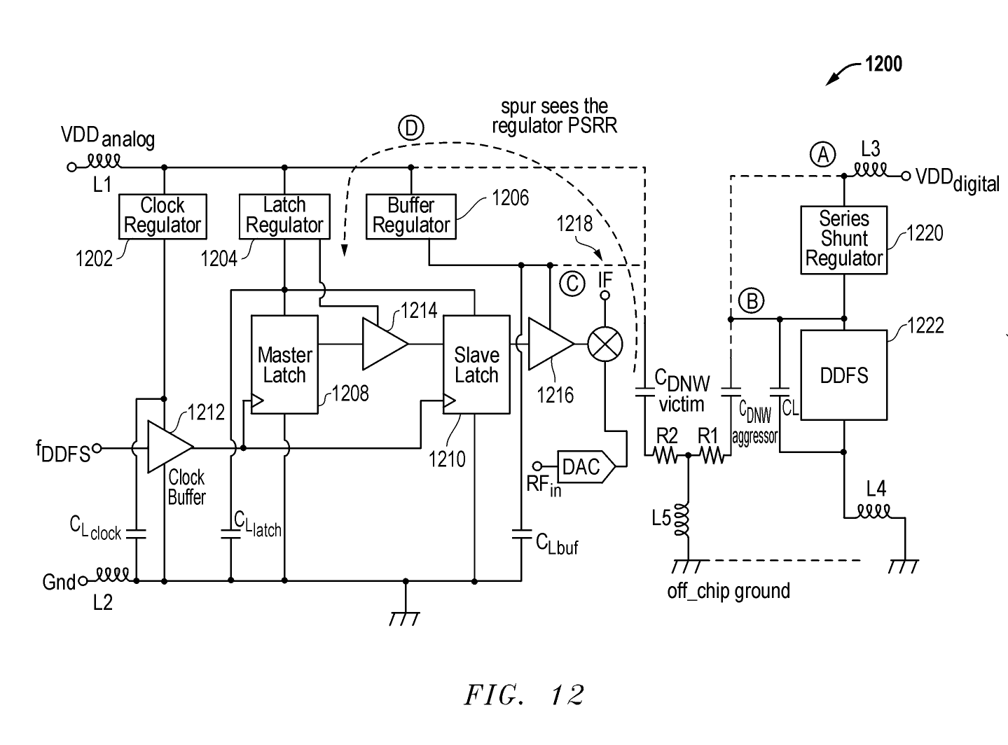

For the aggressor digital block, P+ substrate ties, which are electrically connected by a substrate 1020 ground bond-wire L5 to an off-chip ground (see FIG. 12), should be located at a minimum distance from the digital block edge. For example, P+ substrate ties may be formed as a P+ ring 1010. Locating the P+ ring 1010 relatively close to the DDFS 1014 ensures a relatively low resistance for the substrate-to-ground connection and causes noise injected (by, for example, the digital block) into the substrate 1020 to follow this path, without coupling to the analog circuit 1001. The rings 1008 and 1004 may be native layer rings that have a high resistivity. The ring 1008 presents a high resistance in series with a coupled spur path and, thus, reduces the amount of noise traveling to the analog circuit 1001.

Outside the ring 1008, a second stacked deep N-type well (DNW) and N-type well (NW) wall 1006 may be located to further reduce digital noise contamination of the substrate 1020 surface. As the silicon is lower doped in the volume than at the surface, placing a stacked N-type well wall in the noise path forces the noise to go around the wall which causes the noise to see a higher volume resistance of the substrate 1020. On the victim side, the ring 1004 is positioned to further reduce the noise reaching the analog circuit 1001. In a typical design, the rings 1008 and 1004 are low-doped layers that are provided free in modern deep submicron (e.g., less than 0.13 microns) complementary metal-oxide semiconductor (CMOS) processes. In contrast, the deep N-type well layer requires extra masks and, thus, has an associated additional cost.

In terrestrial/cable TV receivers, employing mixing DAC architectures, the DDFS usually needs to be operated at more than two times the highest LO frequency. If several parallel DDFS cores are implemented to address digital circuit speed issues, then f_{DDFS}/S can be around a few GHz, e.g., 1 GHz. A large f_{LO}+/−1 GHz spur can down-convert a large blocker (f_{blocker}) at 1 GHz−f_{blocker} on top of the desired channel (f_{desired}=f_{LO}−f_{IF}). The constraints for these signal dependent spurs are relatively demanding, e.g., less than −75 dB, particularly in hybrid analog/digital terrestrial receivers. In general, this requires special consideration and minimization of the f_{DDFS}/S power supply and substrate injected spurs. In this case, frequency management may only move the position of the blocker channel to another sensitive blocker position. When this occurs, one solution is to implement multi-ground ring isolation to reduce the substrates spur injection and a multiple series-regulator approach with high forward PSSR for regulators on the victim side and a series-shunt regulator for the digital block with the proper connection of the deep N-type wells.

In general, local oscillator (LO) path circuitry of a mixing DAC includes multiple analog blocks, which may include a clock buffer, synchronization latches, and output buffers that drive a switching section of the mixing DAC. In order to provide proper biasing for the mixing DAC, the output buffers in the LO path generally require a larger voltage than other LO path components. As such, the output buffers usually use a separate buffer regulator. Any deterministic, i.e., data dependent, ripple coupled to the clock buffer may cause additional jitter on the synchronization clock resulting in degraded phase noise performance of the receiver. Minimizing coupling of data dependent ripple from the synchronization latches of the LO path to the clock buffer of the LO path may be achieved by using separate series regulators, e.g., a clock regulator and a latch regulator. In a typical application, a clock buffer power supply regulator should exhibit a relatively high PSRR value. To reduce spur rejection in the LO path, a relatively well balanced differential data path should generally be employed.

It should be appreciated that where a deep N-type well of an IC is connected affects the operation of a receiver. Connecting the deep N-type well of the LO path at a regulated voltage is usually not desirable as substrate noise may be injected into a local power supply without being attenuated by a power supply regulator PSRR. A relatively good choice is to connect the LO path deep N-type well to an unregulated side of a power supply.

With reference to FIG. 12, a relevant portion of a receiver 1200 is depicted that includes a DDFS 1222 that receives power from a power source (VDD_{digital}), via bond-wires L3 and L4, and series-shunt regulator 1220. The receiver 1200 also includes series regulators 1202, 1204, and 1206 that are coupled to a power supply (VDD_{analog}) via bond-wires L1 and L2. A clock buffer 1212 receives power via the series regulator 1202. Master-slave latches 1208 and 1210 and buffers 1214 receive power via the series regulator 1204 and buffers 1216 receive power from the series regulator 1206. An aggressor deep N-type well associated with DDFS 1222 may be coupled at point A or point B and a victim deep N-type well associated with the clock buffer 1212, latches 1208 and 1210, and buffers 1214 and 1216 may be coupled at point C or point D. As noted above, it is usually preferable to couple deep N-type wells of analog and digital blocks to an unregulated side of an associated power supply (see FIG. 12, points A and D). In this case, substrate noise is injected into the unregulated power supply where it may be attenuated by a power supply regulator PSRR (through the reverse PSRR of the aggressor regulator and the forward PSRR of the victim regulator).

As noted above, in addition to the RF signal independent spurs (i.e., +/−N*f_{LO}+/−P*f_{DDFS}), which are generated irrespective of whether an RF receiver has an input signal, an RF receiver also has RF signal dependent spurs (e.g., f_{DDFS}/S−f_{blocker}) that may down-convert a blocker into an intermediate frequency (IF) band. In general, the RF signal independent spurs are additive spurs that do not down-convert blockers into an IF band, while the RF signal dependent spurs are multiplicative spurs that may down-convert blockers into the IF band. Other multiplicative spurs may result from the interaction of mixing DAC distortion (e.g., 3f_{LO}, 4f_{LO}, 5f_{LO}, etc.) with the DDFS frequency (f_{DDFS}) which provides higher multiplicative spurs at f_{DDFS}−3f_{LO}, f_{DDFS}−4f_{LO}, f_{DDFS}−5f_{LO}, etc. While the RF receiver may have lower protection against multiplicative spurs at f_{DDFS}-f_{LO} (DDFS mixing DAC sampling spur) and f_{DDFS}−2f_{LO} (mixing DAC second-order distortion spur aliased by the sampling action), with an f_{DDFS} of around 3 GHz these lower multiplicative spurs fall outside the TV band and, therefore, are not usually of concern, assuming the receiver has a front-end band select filter, e.g., a front-end TV band select filter.

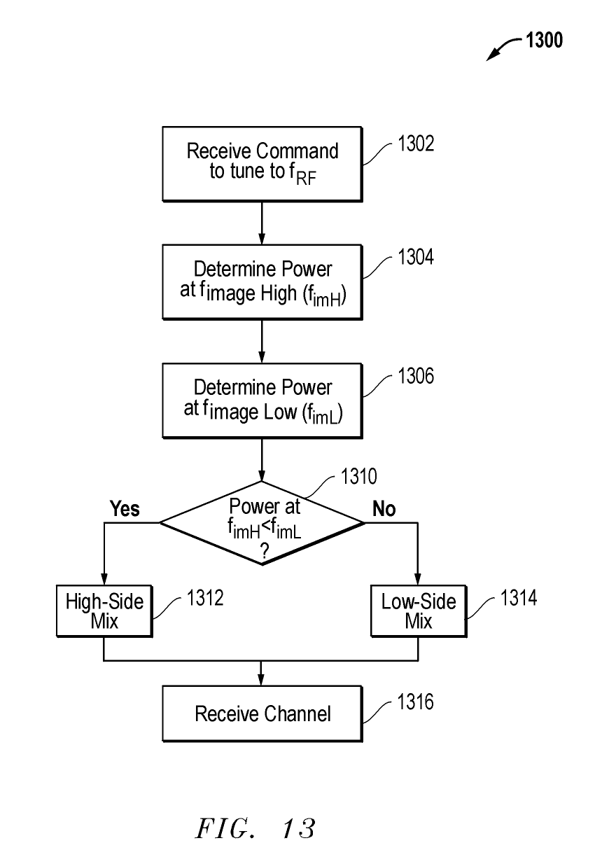

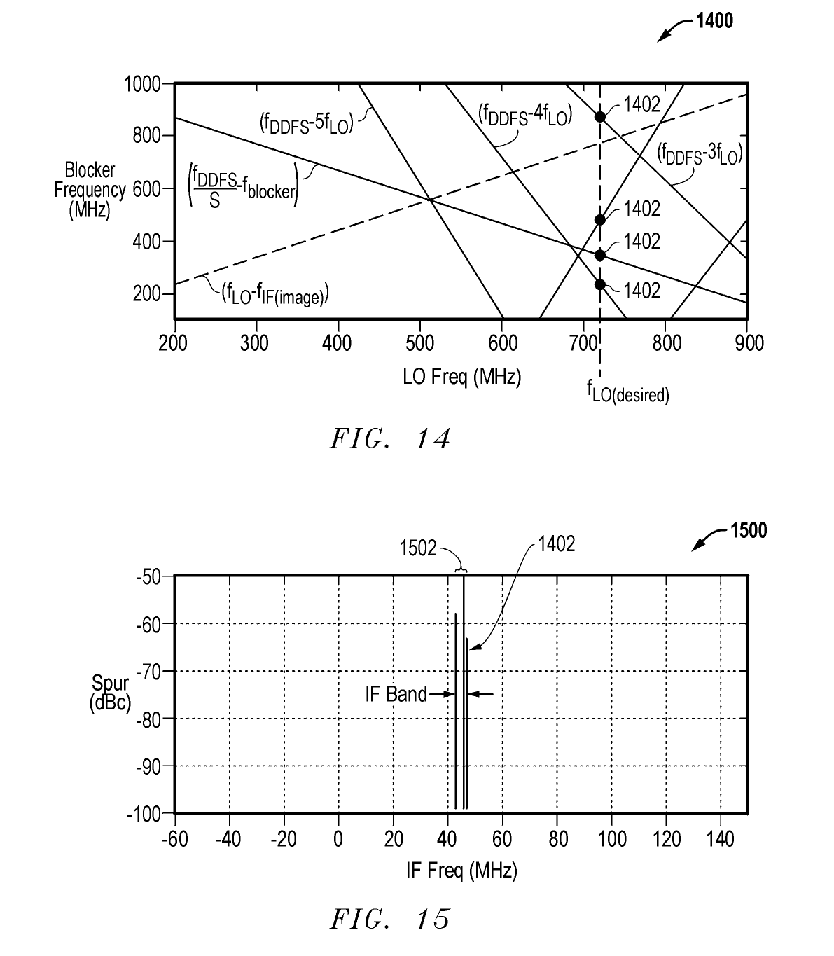

With reference to FIGS. 14 and 15, a spur landscape diagram 1400 is illustrated that plots a number of spurs (represented by diagonal lines) versus local oscillator (LO) frequency (f_{LO}). When blockers 1402 occur at an intersection of a spur diagonal line and an LO frequency vertical line, the blockers 1402 are down-converted into an intermediate frequency (IF) band 1502, as is illustrated in diagram 1500, which plots spur magnitudes in dBc (decibels with respect to carrier). That is, the blockers 1402 are down-converted into the IF band 1502 when the blockers 1402 occur at a frequency that corresponds to an intersection of the LO frequency vertical line and one of the spur diagonal lines. In the diagram 1400, the LO frequency (f_{LO}) is set at 720 MHz and a DDFS frequency (f_{DDFS}) is set at 3.072 GHz. For high-side injection, the LO frequency (f_{LO}) is equal to the desired frequency plus the intermediate frequency (IF), i.e., f_{LO}=f_{desired}+f_{IF}. In sum, an RF receiver has potential blocker issues due to multiplicative spurs at each intersection of an LO frequency vertical line and a spur diagonal line. It should be appreciated that for a given desired frequency (channel) and a given TV standard the value of an IF is fixed (e.g., in the United States the IF for NTSC is 44 MHz), the LO frequency is essentially fixed. However, multiplicative spurs are also dependent on the DDFS frequency, which can be adjusted (up or down) by adjusting values of the input and feedback dividers associated with a phase locked loop (PLL) that provides the DDFS (clock) frequency. Modifying the DDFS frequency causes a corresponding movement of the spur diagonal lines. Thus, at a given LO frequency, the spur diagonal lines may generally be moved to prevent a potential blocker from being down-converted into the IF band of an RF receiver.

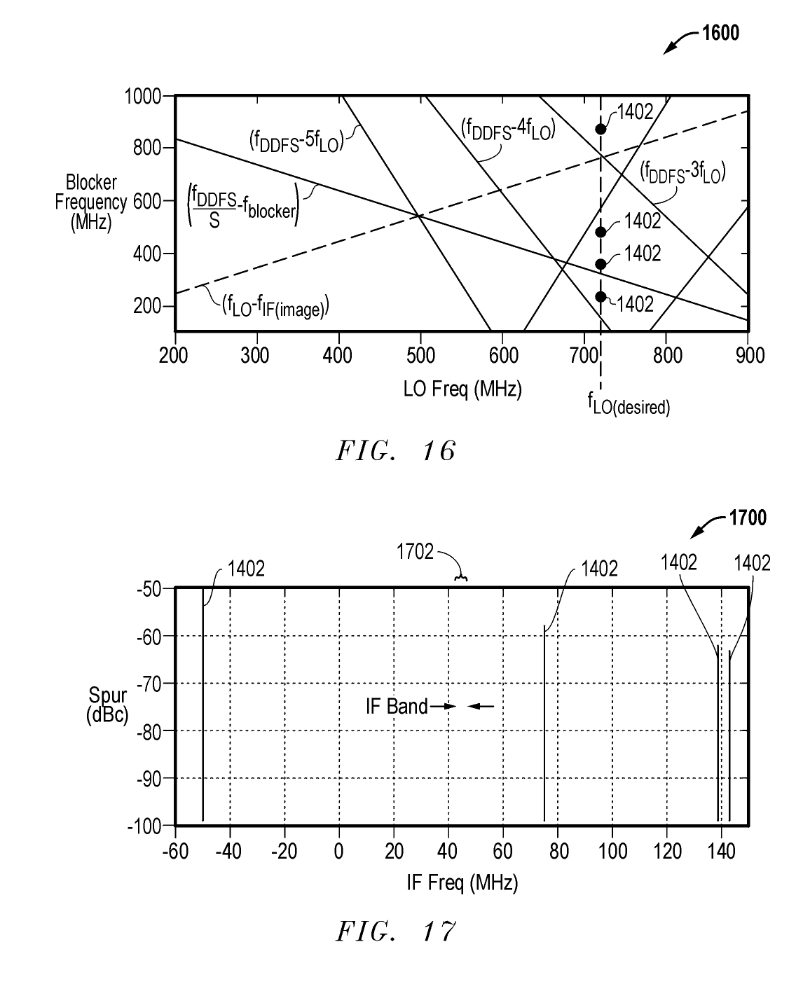

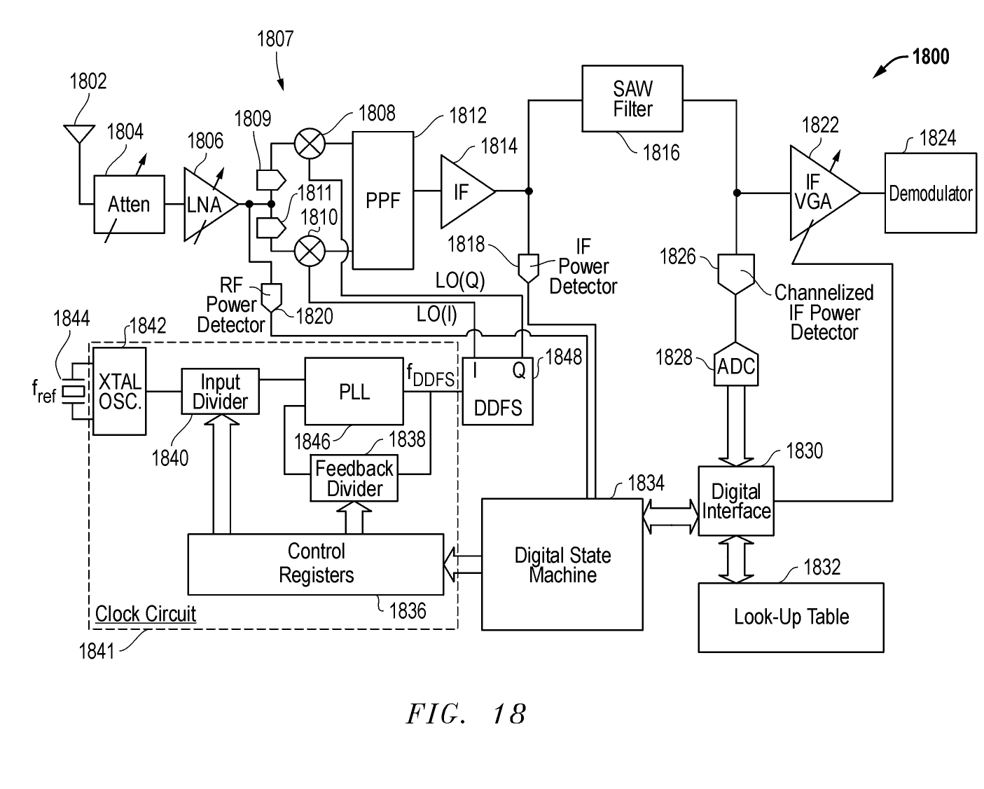

Referring to FIGS. 16 and 17, a spur landscape diagram 1600 is depicted that plots a number of spurs (represented by diagonal lines) versus LO frequency, for an LO frequency of 720 MHz (same as in the diagram 1400) and a DDFS frequency of 2.967 GHz (changed from the nominal 3.072 GHz used in the diagrams 1400 and 1500). As is shown, modifying the DDFS frequency shifts the spur diagonal lines such that the blockers 1402 are not positioned at an intersection of the LO frequency vertical line and any of the spur diagonal lines. Thus, as is illustrated in diagram 1700, which plots spur magnitude in dBc versus IF, the blockers 1402 are not down-converted into IF band 1702 (the blockers 1402 are moved outside the IF band). In a typical implementation, an RF receiver that implements the multiplicative spur frequency management technique and the additive spur frequency management technique shares PLL input and feedback dividers and, thus, uses the same settings for both techniques. In general, an RF receiver may be configured to implement a multiplicative spur management technique by configuring the RF receiver to determine potential blocker positions (frequencies) and associated powers of the blockers. The DDFS frequency may then be selected to reduce both additive and multiplicative spurs in a band of interest, e.g., an IF band.

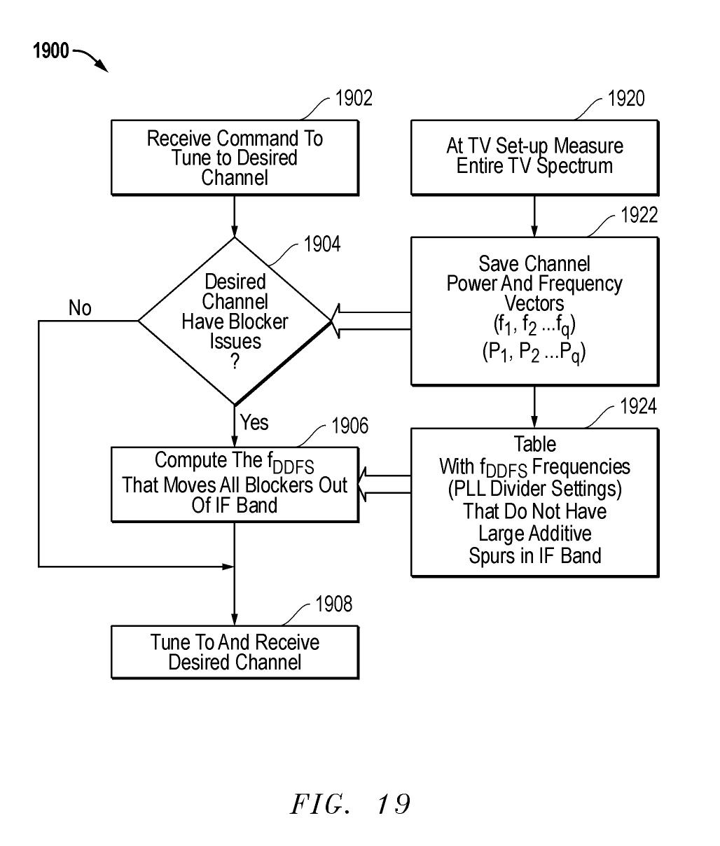

Turning to FIG. 18, an electrical block diagram of a relevant portion of an RF receiver 1800, which is configured to implement a multiplicative spur frequency management technique to reduce spurs within an IF band, is illustrated. The RF receiver 1800 includes a direct digital frequency synthesizer (DDFS) 1848 that drives a mixing digital-to-analog converter (DAC) 1807 with multiple-bit quadrature digital local oscillator (LO) signals (i.e., LO(I) and LO(Q)). A synchronization circuit (not separately shown in FIG. 18) may be implemented between the mixing DAC 1807 and the DDFS 1848. When implemented, the synchronization circuit may include a master-slave latch structure and buffers to ensure that bits associated with quadrature LO signals arrive at respective quadrature inputs of the mixing DAC 1807 at substantially similar arrival times. A clock circuit 1841, which includes, a crystal oscillator 1842, an input divider 1840, a phase locked loop (PLL) 1846, and a feedback divider 1838, provides a DDFS clock signal (f_{DDFS}) to the DDFS 1848 and may provide a synchronization clock signal to the synchronization circuit, when implemented. As is depicted, the receiver 1800 includes a variable RF attenuator 1804 that receives a TV signal from an antenna 1802. An attenuation provided by the attenuator 1804 may be controlled by an RF automatic gain control (AGC) loop (not shown in FIG. 18) such that strong incoming signals are adequately attenuated to avoid non-linearities (e.g., clipping) in an RF front-end, which includes a variable gain low noise amplifier (LNA) 1806 and the mixing DAC 1807, etc. The attenuator 1804 may be implemented using, for example, an off-chip pin diode bridge.

An output of the attenuator 1804 may be coupled to inputs of the LNA 1806 via a balun (not shown in FIG. 18), which converts a signal at the output of the RF attenuator 1804 into a differential signal. The LNA 1806 may be configured to have a programmable gain (in discrete steps) that is set by an RF AGC loop. Outputs of the LNA 1806 may be respectively coupled to inputs of the mixing DAC 1807, via a programmable harmonic reject filter (not shown in FIG. 18), which, when implemented, is configured to improve harmonic rejection performance of the receiver 1800. An RF power detector 1820, which measures RF power for the RF AGC loop, is also coupled to the outputs of the LNA 1806. The mixing DAC 1807 includes a pair of quadrature mixing DACs that each have two main sub-blocks, i.e., RF transconductance sections 1809 and 1811 and switching sections (mixers) 1808 and 1810. The RF transconductance sections may be configured as, for example, RF transconductance DACs. The RF transconductance sections 1809 and 1811 convert an RF input voltage into an RF current, based on a value of each local oscillator (LO) bit provided by the DDFS 1848.

The outputs of the mixers 1810 and 1808 are provided to inputs of a poly-phase filter (PPF) 1812, e.g., a fifth-order PPF, that ensures a relatively high value image rejection level over a relatively wide intermediate frequency (IF) range. Outputs of the PPF 1812 are coupled to respective inputs of an IF amplifier 1814 that sets the receiver 1800 gain at a desired value based on the application, e.g., cable or terrestrial TV. Outputs of the amplifier 1814 are coupled to inputs of an off-chip surface acoustic wave (SAW) filter 1816 and to an IF power detector 1818, which measures IF power for IF AGC. Outputs of the off-chip SAW filter 1816 are coupled to inputs of an analog demodulator 1824, via an IF variable gain amplifier (VGA) 1822. Outputs of the SAW filter 1816 are also coupled to inputs of a channelized IF power detector 1826, whose output is coupled to an input of an analog-to-digital converter (ADC) 1828, whose output is coupled to an input of a digital interface 1830, e.g., an inter-integrated circuit (I2C) interface. The detector 1826 is employed to facilitate characterization of a frequency spectrum of interest. A first port of the interface 1830 is coupled to a port of a control circuit 1834, such as a digital state machine (DSM), and a second port of the interface 1830 is coupled to a port of a look-up table 1832, which is employed to facilitate multiplicative spur frequency management. The DSM 1834 is configured to access the look-up table 1832 via the interface 1830. An output of the DSM 1834 is coupled to an input of a control register 1836, whose first output is coupled to a control input of the input divider 1840 and whose second output is coupled to a control input of the feedback divider 1838 of the PLL 1846.

Moving to FIG. 19, a routine 1900 for implementing a multiplicative spur frequency management technique for reducing spurs within an intermediate frequency (IF) band of the RF receiver 1800 is illustrated. With reference to block 1920, during a set-up process, a frequency spectrum of interest, e.g., a TV spectrum or at least a portion of the TV spectrum, is scanned (characterized) to determine both a frequency location and a power level of all channels available at a given location. By characterizing the spectrum, knowledge of channels which may act as blockers, when a desired channel is received, is acquired. The spectrum may be characterized by, for example, measuring IF power using the detector 1826, which is configured as a channelized IF power detector, for a number of selected channels. Next, in block 1922, vector pairs, i.e., received channel powers (p1, p2, . . . pq) and associated frequency vectors (f1, f2, . . . fq), may be saved in the look-up table 1832. As multiplicative spurs have a known formula, when a given desired channel is to be received the DSM 1834 is utilized to compute whether a blocking issue may exist. As noted above, additive spurs may also be considered when selecting a DDFS frequency. As a demodulator can tolerate small changes in an IF channel position, for a given LO frequency there are usually multiple values for the input divider 1840 and the feedback divider 1838 associated with the PLL 1846 that provide a DDFS frequency with relatively small associated in-band additive spurs. With reference to block 1924, the look-up table 1832 may also store multiple DDFS frequencies that do not have large IF band additive spurs. The DDFS frequencies may then be utilized when choosing a DDFS frequency that does not have multiplicative spurs that convert large blockers into the IF band.

Turning to block 1902, following set-up, a command is received to tune a receiver to a desired channel. Next, in block 1904, the DSM 1834 determines whether the desired channel has blocker issues. If not, control transfers to block 1908, where the desired channel is received. In block 1904, when the desired channel has blocker issues, control transfers to block 1906. In block 1906, a DDFS frequency is selected that moves all (or most) blockers out of the IF band of the RF receiver. For a given blocking profile (position of strong undesired channels), the DSM 1834 selects the DDFS frequency that moves substantially all of the high-power blockers out of the IF band. Low-power blockers can be tolerated even if the low-power blockers fall at a receiver sensitive point if the signal-to-noise ratio (SNR) degradation is relatively low (e.g., spur lower than −75 to −80 dBc). The DSM 1834 may implement a relatively simple frequency management routine that performs an exhaustive search of all valid PLL divider combinations that provide a low additive spur level and pick the combination that either moves all multiplicative spurs out of the IF band or provides the lowest interference power. Alternatively, the DSM 1834 may implement a relatively complex frequency management routine that utilizes the expressions for the blocker sensitive frequencies. In either case, values for the input and feedback dividers 1840 and 1838 are set by the DSM 1834, via the control registers 1836.

According to another aspect of the present disclosure, dynamic automatic gain control (AGC) loop trip point adjustment techniques may be implemented to lower distortion in an RF receiver. In general, a relatively important specification for a TV receiver (tuner) is an undesired channel to desired channel (U/D) power ratio that can be tolerated while providing a required SNR value (e.g., an SNR of 15 dB for NTSC digital TV reception). In a typical TV receiver, U/D power ratio is dominated by equivalent noise figure (NF), RF signal path non-linearities, and mixer local oscillator (LO) path harmonics. Equivalent NF depends on a noise contribution of front-end stages (e.g., attenuator, LNA, and mixer) of the receiver. Noise contribution of intermediate frequency (IF) stages to the equivalent NF of a receiver is usually negligible, due to a large gain (e.g., 30 dB) of one or more stages prior to the IF stages. In general, attenuation in an RF front-end stage directly impacts NF performance of an RF receiver. To increase the U/D power ratio of an RF receiver it is usually desirable to engage a front-end attenuator as late as possible when a total input power is increasing. In the RF signal path, it is also desirable to reduce second-order and third-order distortions (LNA and mixer RF input second-order and third-order distortions), since the distortions cannot usually be frequency managed. On the other hand, the LO spurs and the LO harmonics can be frequency managed since the LO spurs and LO harmonics depend on the DDFS (clock) frequency. In an RF receiver employing a differential mixer architecture, odd LO harmonics usually dominate, as even harmonics, which are usually attributable to device mismatches in the LO path and mixer differential stages, are usually significantly smaller in amplitude than the odd harmonics.

According to one or more embodiments, an automatic gain control (AGC) loop of an RF receiver is controlled responsive to power detectors connected at various points in a signal path of the receiver. In one embodiment, a first power detector is employed in an RF path at an input of a mixer (to avoid or reduce signal clipping at the RF input transconductance stage of the mixer) and a second power detector is employed in an IF path at an output of an IF driver (to avoid or reduce signal clipping at an output stage of the IF path). In this manner, an appropriate boundary between noise limited performance and distortion limited performance may be achieved by choosing appropriate AGC loop power detector trip points. When a desired channel is not accompanied by adjacent channels that are at sensitive distortion positions (e.g., f_{RF}/2 and f_{RF}/3 for second-order and third-order distortion and 2f_{LO}−f_{IF}, 3f_{LO}−f_{IF}, etc. for the LO harmonics), an RF path AGC loop power detector trip point may be set to a relatively high level such that signal clipping in the RF path is avoided. In this case, the front-end attenuator should usually be designed to reduce the gain as late as possible when input power is increasing. For the noise-limited case, this facilitates reception of weak desired channels in the presence of strong undesired channels (blockers), since the receiver equivalent NF is not strongly degraded by a large attenuation in front of the receiver LNA. If a blocker is located at a sensitive distortion position, the RF path AGC loop trip point should usually be set at a relatively low value in order to reduce distortion products that increase (e.g., exponentially) with blocker power (e.g., 2 dB second-order distortion per 1 dB of blocker power and 3 dB third-order distortion per 1 dB of blocker power). In a typical RF receiver, LO harmonics are generally rejected by employing front-end filters or harmonic rejection mixers. In a typical situation, distortion products of interest are usually attributable to second-order and third-order non-linearities in the RF signal path.

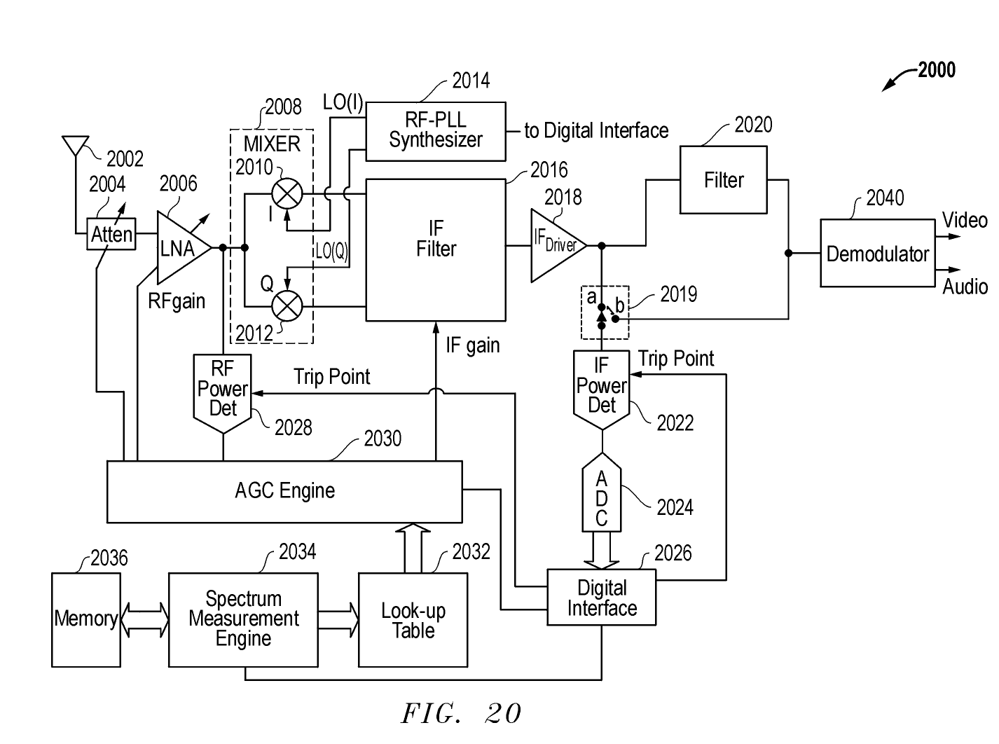

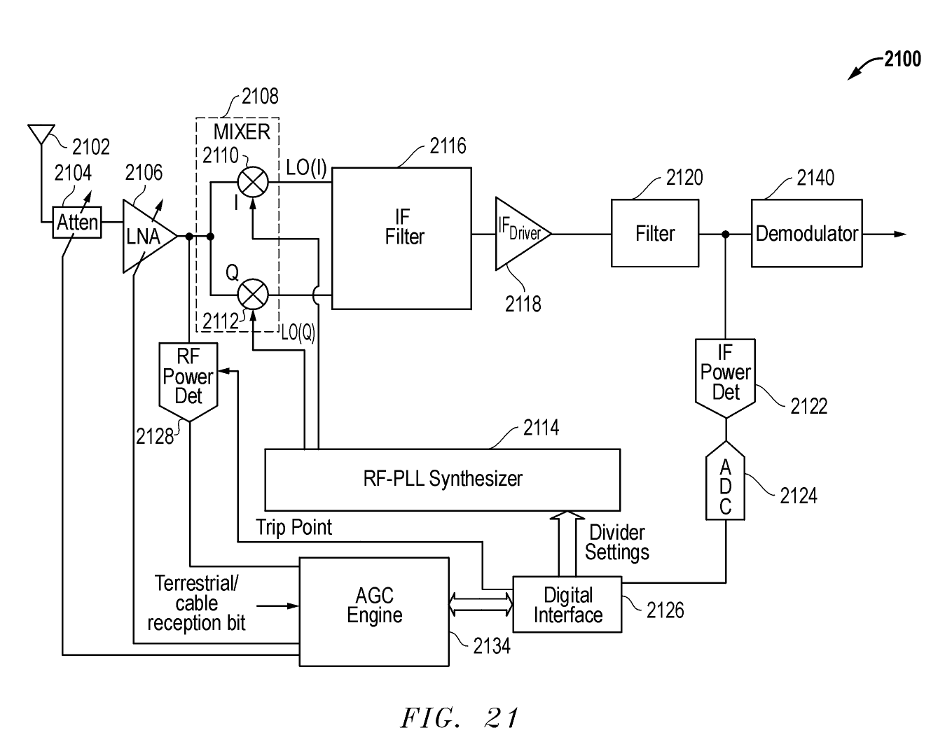

As noted above, to improve balance between noise and distortion performance, AGC loop trip points may be adjusted based on blocker locations (i.e., blocker frequencies). With reference to FIG. 20, an RF receiver 2000 is illustrated that employs dynamic AGC loop trip points. The receiver 2000 receives an RF input signal via an antenna 2002. The antenna 2002 is coupled to an input of a variable RF attenuator 2004, whose output is coupled to an input of a variable gain low noise amplifier (LNA) 2006. An output of the LNA 2006 is coupled to an input of mixer 2008, which in the illustrated case includes quadrature mixers 2010 and 2012, which may be mixing DACs. The quadrature mixers 2010 and 2012 receive quadrature local oscillator (LO) signals from an RF-PLL synthesizer 2014, which may be a direct digital frequency synthesizer (DDFS). An input of RF power detector 2028 is coupled to the input of the mixer 2008 and an output of the RF power detector 2028 is coupled to an input of an AGC control circuit (AGC engine) 2030, such as a digital state machine (DSM), that sets an attenuation of the attenuator 2004 and a gain of the LNA 2006 responsive to the RF power detector 2028. Outputs of the mixer 2008 are coupled to inputs of an IF filter 2016, which may provide gain (responsive to the AGC engine 2030), as well as filtering.

The filter 2016 may be, for example, a passive or an active fifth-order polyphase filter (PPF). An output of the filter 2016 is coupled to an input of an IF driver (amplifier) 2018, whose output is coupled to an input of an off-chip filter 2020, e.g., a SAW filter. An output of the filter 2020 is coupled to an input of a demodulator 2040. An input of IF power detector 2022 may be coupled to the output of the filter 2020, via switch 2019, for frequency spectrum characterization. In this case, the LO frequency is consecutively tuned to each TV channel position and the power, after the channel selection filter (e.g., SAW filter), is measured to determine if the channel is present at the given receiver position. In normal terrestrial TV reception, only a few of the available TV channels are present. Alternatively, the input of the detector 2022 may be coupled to the input of the filter 2020, via the switch 2019, during normal operation of the receiver 2000. An output of the detector 2022 is coupled to an input of an analog-to-digital converter (ADC) 2024, whose output is coupled to an input of digital interface 2026, e.g., an inter-integrated circuit (I2C) interface. Respective outputs of the interface 2026 are coupled to control inputs of the detectors 2022 and 2028. A port of the digital interface 2026 is coupled to a port of a spectrum measurement engine 2034 to facilitate reading of power levels associated with different channels.

As is illustrated, the receiver 2000 includes a memory 2036 that stores frequency positions of large power channels. The frequency positions and power levels of the large power channels may be determined at power-up of the receiver 2000. For example, a spectrum of interest, e.g., a TV spectrum, may be scanned by stepping the synthesizer 2014 over all channel positions and measuring an output power (with the detector 2022) of the receiver 2000 at the output of the filter 2020, where only the desired channel is present. Typically, all of the undesired channels are rejected by the steep bandpass characteristic of the SAW filter. In this embodiment, during initial operation of the receiver 2000, a spectrum measurement control circuit (spectrum measurement engine) 2034, such as a digital state machine (DSM), determines if blockers are located at sensitive distortion positions and stores the information in the memory 2036. In various embodiments, the memory 2036 may also store the different DDFS frequencies (that do not have large in-band additive spurs) for frequency management of the multiplicative spurs. A look-up table 2032, which is coupled between the spectrum measurement engine 2034 and the AGC engine 2030 may be implemented to set AGC loop trip points responsive to whether blockers are located at sensitive distortion positions.

The RF AGC loop trip point may then be set by the AGC engine 2030, via the digital interface 2026, to a relatively low level to minimize distortion products when blockers are located at sensitive distortion positions. When blockers are not located at sensitive distortion positions, the RF AGC loop trip point may be set to a relatively high level to reduce a noise floor of the receiver 2000 to a minimum level. In this manner, relatively weak channels may be received at a reasonable signal-to-noise ratio (SNR). In this embodiment, AGC loop trip points may be determined (from the look-up table 2032) in a relatively short time period, as blocker positions are known from the measured spectrum. However, it should be appreciated that the implementation of the memory 2036 to store blocker positions increases the cost of the receiver 2000. In a typical demodulator, memory is employed to store firmware data and code. The added memory required by the frequency management technique is relatively small, as compared to the demodulator memory and, as such, the cost for employing the added memory is relatively low.

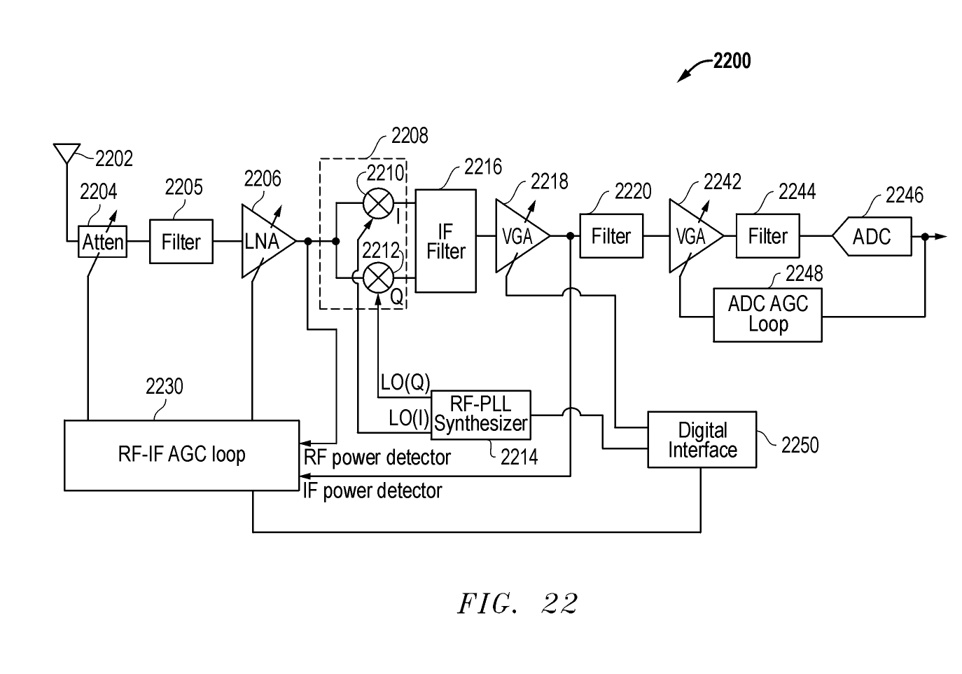

With reference to FIG. 21, an RF receiver 2100 is illustrated that is configured to adjust an RF AGC loop trip point according to another aspect of the present disclosure. The receiver 2100 is generally lower in cost than the receiver 2000, as the receiver 2100 does not implement a memory to store frequency positions of large power channels. As is illustrated, an input of a variable RF attenuator 2104 of the receiver is coupled to an antenna 2102. An output of the attenuator 2104 is coupled to an input of a variable gain low noise amplifier (LNA) 2106. An output of LNA 2106 is coupled to an input of mixer 2108, which in the illustrated case includes quadrature mixers 2110 and 2112, which may be mixing DACs. The quadrature mixers 2110 and 2112 receive quadrature local oscillator (LO) signals from an RF-PLL synthesizer 2114, which may be a direct digital frequency synthesizer (DDFS). An input of RF power detector 2128 is coupled to the input of the mixer 2108 and an output of the RF power detector 2128 is coupled to an input of an AGC control circuit (AGC engine) 2134, such as a digital state machine (DSM), that sets an attenuation level of the attenuator 2104 and a gain of the LNA 2106 responsive to the RF power detector 2128. Outputs of the mixer 2108 are coupled to inputs of an IF filter 2116, which may provide gain (responsive to the AGC engine 2134) as well as filtering. The filter 2116 may be, for example, a passive or an active fifth-order polyphase filter (PPF). An output of the filter 2116 is coupled to an input of an IF driver (amplifier) 2118, whose output is coupled to an input of an off-chip filter 2120, e.g., a SAW filter. An output of the filter 2120 is coupled to an input of a demodulator 2140. An input of IF power detector 2122 is coupled to an output of the filter 2120. An output of the IF power detector 2122 is coupled to an input of an analog-to-digital converter (ADC) 2124, whose output is coupled to an input of digital interface 2126, e.g., an inter-integrated circuit (I2C) interface. An output of the interface 2126 is coupled to a control input of the RF power detector 2128.

In this embodiment, the IF power detector 2122 does not employ an adjustable trip point, as the detector 2122 is employed to determine an IF output power at the output of the filter 2120 to facilitate frequency spectrum characterization. A trip point for the RF power detector 2128 sets the RF input power level at which the attenuator 2104 starts to attenuate the RF input signal (and, in turn, degrade the NF performance) of the receiver 2100. In this embodiment, each time a different channel is selected, the AGC engine 2134 consecutively sets, via the interface 2126, the input and feedback dividers of the RF-PLL synthesizer 2114 to values that tune the distortion sensitive points. This allows the receiver to evaluate if large blockers are present at sensitive frequencies for the currently selected desired channel. When the detector 2122 indicates that a blocker is present at the selected channel sensitive points (e.g., N*LO harmonics), the AGC engine 2134 determines where the RF AGC loop trip point should be set in order to substantially comply with U/D specifications. If no blockers are present, then the RF AGC loop trip point may be maintained at a maximum value that does not result in clipping of the RF input signal. In general, the receiver 2100 is designed to minimize impact of any distortion or spur related reciprocal mixing effect. As is illustrated, the AGC engine 2134 also receives a terrestrial/cable reception bit, which indicates whether the receiver 2100 is operating in terrestrial (analog) mode or cable (digital) mode. As is discussed in further detail below, when the receiver 2100 is a hybrid terrestrial/cable receiver, the operation of the receiver 2100 may be varied based on the mode. In order to provide acceptable performance in a real-world environment, the number of frequency points where measurements are performed should be kept at a relatively low number in order to not increase channel switching times to undesirable levels. In general, the AGC loop settling time should also be minimized. In general, it is desirable to design a receiver such that the receiver has a relatively low number of impairments (a mixing DAC generally has fewer LO harmonics than a standard square-wave mixer).

In hybrid RF receivers, such as terrestrial/cable TV receivers, the spectrums for the different modes of operation are different. That is, in the cable mode, while the cable TV spectrum is densely populated with channels, all of the cable channels have substantially similar power levels. In this case, the number of intermodulation distortion products may be relatively large due to the multitude of channels present at an input of the receiver. As such, an RF AGC trip point of the receiver may be set to a relatively low level to meet the composite triple beat (CTB) and composite second-order (CSO), i.e., third-order and second-order, distortion specifications. However, since the desired cable channel power is relatively high, the receiver is not noise limited and can tolerate a significant amount of front-end attenuation, which directly impacts NF. In contrast, in the terrestrial mode, while the terrestrial TV spectrum is sparsely populated with channels, the channels may have very different power levels (e.g., channel power levels up to 0 dBm). Receiving channels with wide ranging power levels (e.g., from −85 dBm to 0 dBm) may result in stringent requirements for an AGC loop. In this situation, an RF AGC trip point may be set relatively high to receive a selected weak channel. This typically prevents burying the desired channel into the noise floor through front-end attenuation. In this case, the front-end attenuator may be limited to attenuating only when a blocker is present at a sensitive distortion position.

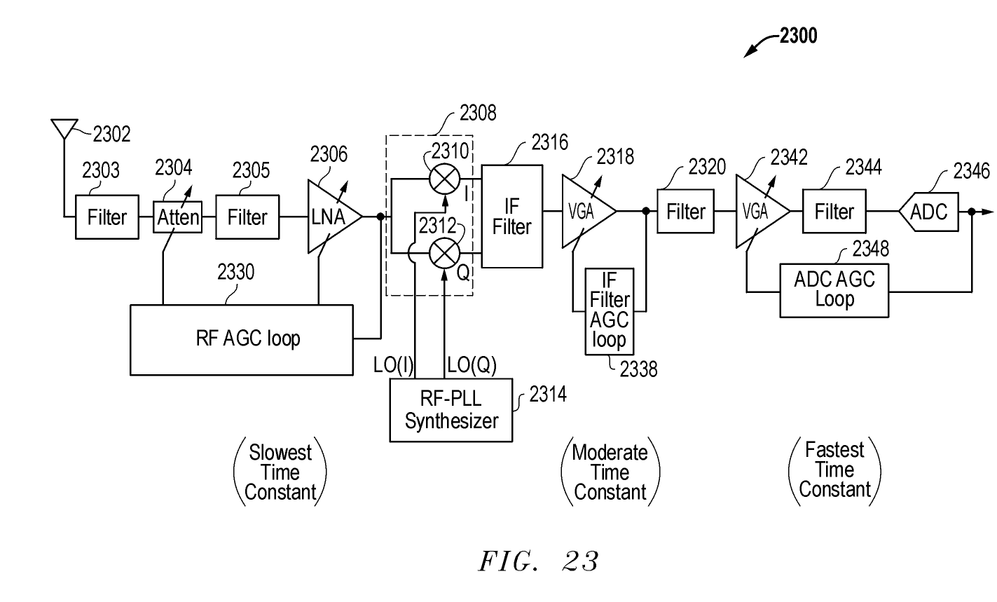

Turning to FIG. 22, an RF receiver 2200 is illustrated that is configured to adjust a variable RF attenuator 2204 and a variable gain low noise amplifier (LNA) 2206, according to another aspect of the present disclosure. As is illustrated, an antenna 2202 is coupled to an input of the RF attenuator 2204 of the receiver 2200. An output of the attenuator 2204 is coupled to an input of a filter 2205. An output of the filter 2205 is coupled to an input of the LNA 2206. An output of LNA 2206 is coupled to an input of a mixer 2208, which in the illustrated case includes quadrature mixers 2210 and 2212, which may be mixing DACs. The quadrature mixers 2210 and 2212 receive quadrature local oscillator (LO) signals from an RF-PLL synthesizer 2214, which may be a direct digital frequency synthesizer (DDFS). A first input of RF-IF AGC loop 2230 is coupled to an internal RF power detector (not separately shown) and a second input of the RF-IF AGC loop 2230 is coupled to an IF power detector (not separately shown).

The first input of the RF-IF AGC loop 2230 is coupled to the input of the mixer 2208 and the second input of the RF-IF AGC loop 2230 is coupled to an input of filter 2220. The RF-IF AGC loop 2230 includes a control circuit, such as a digital state machine (DSM), that sets a gain of the LNA 2206 and an attenuation level of the attenuator 2204. Outputs of the mixer 2208 are coupled to inputs of an IF filter 2216, which may provide gain as well as filtering. The filter 2216 may be, for example, a passive or an active fifth-order polyphase filter (PPF). An output of the filter 2216 is coupled to an input of a first variable gain amplifier (VGA) 2218, whose output is coupled to an input of an off-chip filter 2220, e.g., a SAW filter. An output of the filter 2220 is coupled to an input of a second VGA 2242, whose output is coupled to an input of filter 2244, whose output is coupled to an input of ADC 2246. An ADC AGC loop 2248 is coupled between an output of the ADC 2246 and a control input of the VGA 2242.

As is illustrated, the receiver 2200 includes two AGC loops, i.e., the RF-IF AGC loop 2230 and the ADC AGC loop 2248. As is typical, the receiver 2200 implements filters and amplifiers in an RF path and an IF path. In receivers that are subject to strong blockers, implementing the filter 2205 before the LNA 2206 generally reduces distortion in the receiver 2200. The filter 2205 is employed to attenuate far-out blockers and reduce aggregate input power to an input of the LNA 2206. In general, a design compromise, which directly impacts overall receiver NF is required between filter rejection of far-out blockers and filter insertion loss. The attenuator 2204 is implemented to reduce input power in the case of strong close-in blockers. A harmonic reject filter (not shown in FIG. 22) may be employed between the LNA 2206 and the mixer 2208 to improve harmonic rejection performance and reduce RF distortion of the receiver 2200. When implemented, the harmonic reject filter also reduces the aggregate input power at an input of the mixer 2208, which is illustrated as a down-converting complex mixer. The IF filter 2216 is employed to convert an IF signal back to the real-domain (or to maintain the complex IF path). A gain of the VGA 2218 may be controlled by an AGC loop via a digital interface 2250, e.g., an inter-integrated circuit (I2C) interface, or controlled in an independent manner via the digital interface 2250. The filter 2220 may be implemented to further reduce far-out blockers (or maintain channelization when the filter 2220 takes the form of a surface acoustic wave (SAW) filter). The second VGA 2242 maintains a substantially constant signal level at an input of an analog-to-digital converter (ADC) 2246, which converts an analog IF signal into a digital IF signal, to improve sampling. The filter 2244, which may take the form of a second SAW filter in the receiver signal path, may be employed to reduce ADC 2246 aliasing of the IF path wideband noise and distortion.

With reference to FIG. 23, an RF receiver 2300 is illustrated that employs three AGC loops that each implement a power detector (within RF AGC loop 2330, IF filter AGC loop 2338, and ADC AGC loop 2348) to determine whether an associated signal path experiences a relatively large amplitude signal (which may be a desired or undesired blocker channel). The receiver 2300 includes a filter 2303, whose input is coupled to antenna 2302 and whose output is coupled to an input of a variable attenuator 2304. An output of the attenuator 2304 is coupled to an input of filter 2305, whose output is coupled to an input of a variable gain low noise amplifier (LNA) 2306. An output of the LNA 2306 is coupled to an input of mixer 2308, which in the illustrated case includes quadrature mixers 2310 and 2312, which may be mixing DACs. The quadrature mixers 2310 and 2312 receive quadrature local oscillator (LO) signals from an RF-PLL synthesizer 2314, which may be a direct digital frequency synthesizer (DDFS). A first input of RF AGC loop 2330 is coupled to the input of the mixer 2308. The RF AGC loop 2330 includes a control circuit, such as a digital state machine (DSM), that sets a gain of the LNA 2306 and an attenuation level of the attenuator 2304. Outputs of the mixer 2308 are coupled to inputs of an IF filter 2316, which may provide gain as well as filtering. The filter 2316 may be, for example, a passive or an active fifth-order polyphase filter (PPF). An output of the filter 2316 is coupled to an input of a variable gain amplifier (VGA) 2318, whose output is coupled to an input of an off-chip filter 2320, e.g., a SAW filter. An output of the filter 2320 is coupled to an input of a VGA 2342, whose output is coupled to an input of filter 2344, whose output is coupled to an input of ADC 2346. An ADC AGC loop 2348 is coupled between an output of the ADC 2346 and a control input of the VGA 2342.

In the receiver 2300, an analog RF power detector is incorporated within the RF AGC loop 2330, an analog IF power detector is incorporated within the IF filter AGC loop 2338, and a digital power detector is incorporated within the ADC AGC loop 2348. Employing three independent AGC loops to set associated trip points provides flexibility. However, a receiver that employs an inner AGC loop requires implementing different time constants for the AGC loop to ensure stability (if the AGC loops are cascaded there is usually no particular time constant requirements to maintain stability). In TV applications, the received signal may be subject to multi-path fading that can result in either fast or slow power level variations that may overdrive some of the receiver signal path blocks. In general, the RF power is substantially constant even if some of the channels in the spectrum experience fading. As such, the RF AGC time constant may be low (e.g., seconds) such that the received signal does not track any fading phenomena. In contrast, the IF AGC loop and the ADC AGC loop may see relatively large power variations. Since it is generally easier to achieve larger dynamic range in a filter than in an ADC, the ADC AGC loop is usually designed wideband to follow the fading and relax ADC dynamic range requirements.

In general, a better compromise in terms of signal level setting and AGC time constants may be achieved with the architecture of the receiver 2200, which only employs two independent AGC loops. In the receiver 2200 of FIG. 22, a relatively fast AGC loop is employed around the filter 2244, which substantially maintains a signal level at the input of the ADC 2246 in the presence of signal fading. As is illustrated, the receiver 2200 employs a combined RF-IF AGC loop 2230 that samples both an input signal level to the mixer 2208 and an input signal level to the filter 2220 and sets both the RF and IF amplifier gain levels. Using separate AGC RF and IF trip points allows either the RF or the IF power level to drive the AGC loop. As the signal path includes significant bandpass filtering around a desired channel, in the presence of a far-out blocker the RF power detector drives the AGC loop. In the presence of close-in blockers, the IF power detector drives the AGC loop. Employing only two AGC loops in an RF receiver facilitates selection of AGC loop time constants that provide a good solution to both static and dynamic power level variations. The AGC time constants are set based on the point where the dynamic range is limited. If the ADC is the dynamic range bottleneck, then the ADC AGC may employ a relatively large bandwidth, while the RF AGC employs a relatively narrow bandwidth. On the other hand, if the mixer is the linearity limiting factor, then the RF AGC is set wideband and the ADC AGC is set narrowband. The AGC time constants are dependent on the amount of filtering in the signal path before the AGC power detector. If only modest filtering is employed (e.g., in a TV receiver that does not include a tracking filter), then the broadband RF spectrum is less likely to experience large fading and the RF AGC may be set to a relatively narrow bandwidth.

An analog TV receiver usually requires a relatively high signal-to-noise ratio (SNR), e.g., about 55 dB, for acceptable reception. In a typical case, it is usually desirable to minimize a NF of an analog TV receiver, as an analog TV receiver is typically less susceptible to distortion. To minimize an NF of an analog TV receiver, an AGC trip point for the RF path may be set to a relatively high level, e.g., slightly below an RF input signal clipping level. In contrast, a digital TV receiver normally requires a relatively low SNR, e.g., 15 to 20 dB, for acceptable reception. However, digital TV receivers are usually sensitive to distortion in the signal path which may cause relatively large spectral regrowth. As such, a front-end RF attenuator of a digital TV receiver is usually set to reduce a level of an RF input signal. For a digital TV receiver, the AGC RF trip point can usually be set to a relatively low level to reduce distortion, as the receiver can tolerate a larger NF degradation due to front-end attenuation. In general, knowledge of TV channel type (e.g., analog/digital) may be used to determine optimal AGC loop settings for a hybrid (cable/terrestrial) TV receiver.

A channel type may be determined in the analog domain in a number of different ways. For example, horizontal synchronization pulses (detected by a synchronization pulse detector) that are present in an analog TV channel may be used to indicate an analog channel. In general, horizontal synchronization pulses are relatively large in amplitude and, as such, are identifiable even when the pulses have not settled in the signal path of a receiver. It should be appreciated that this type of information is usually only available following acquisition by a demodulator. In this case, time lag in determining channel type, due to a time period required for demodulator lock, may lead to undesirable RF AGC loop trip point settings that cause relatively large transients in a signal path of the receiver. As another example, an analog channel detector may be implemented at an input to an off-chip filter. The analog channel detector may employ filters with predefined corner frequencies to sense power differences at given frequencies in a TV channel band and, in this manner, indicate whether a received signal is a digital signal or an analog signal. For example, in the NTSC analog TV standard (U.S.), the picture carrier is about 13 dB stronger than the audio carrier and the carriers are located at different frequency offsets within the desired channel and can be sensed with dedicated video and audio bandpass filters. It is contemplated that a channel type detector may take other forms. For example, other analog or digital channel specific characteristics may be used to determine a channel type. As one example, the fact that digital TV channel power spectrum is relatively uniform, while the analog TV channel power spectrum has large variations (attributable to, for example, video, chroma, and sound corners), may be used to determine a channel type. Irrespective of how channel type is determined, the RF AGC trip point is usually set to a relatively high level for an analog channel and to a relatively low level for a digital channel.

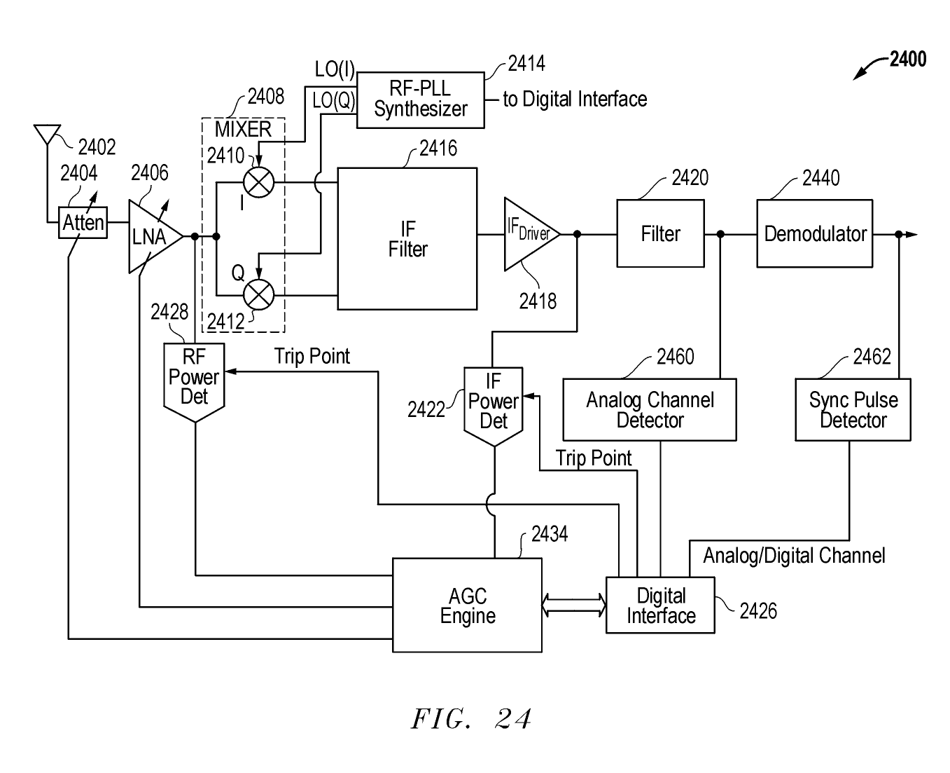

With reference to FIG. 24, a hybrid TV receiver 2400 that is configured to employ analog sensing of a channel type is illustrated according to another aspect of the present disclosure. The receiver 2400 receives an RF input signal via an antenna 2402. The antenna 2402 is coupled to an input of a variable RF attenuator 2404, whose output is coupled to an input of a variable gain low noise amplifier (LNA) 2406. An output of the LNA 2406 is coupled to an input of mixer 2408, which in the illustrated case includes quadrature mixers 2410 and 2412, which may be mixing DACs. The quadrature mixers 2410 and 2412 receive quadrature local oscillator (LO) signals from an RF-PLL synthesizer 2414, which may be a direct digital frequency synthesizer (DDFS). An input of RF power detector 2428 is coupled to the input of the mixer 2408 and an output of the RF power detector 2428 is coupled to a first input of an AGC control circuit (AGC engine) 2434, such as a digital state machine (DSM), that sets a gain of the LNA 2406 and an attenuation level of the attenuator 2404 responsive to the RF power detector 2428. Outputs of the mixer 2408 are coupled to inputs of an IF filter 2416, which may provide gain (responsive to the AGC engine 2430), as well as filtering. The filter 2416 may be, for example, a passive or an active fifth-order polyphase filter (PPF). An output of the filter 2416 is coupled to an input of an IF driver (amplifier) 2418, whose output is coupled to an input of an off-chip filter 2420, e.g., a SAW filter. An output of the filter 2420 is coupled to an input of a demodulator 2440.

An input of IF power detector 2422 is coupled to the input of the filter 2420 and an output of the IF power detector 2422 is coupled to a second input of the AGC engine 2434. An input of an analog channel detector 2460 is coupled to the input of the filter 2420 and an output of the detector 2460 is coupled to a first input of the digital interface 2426, e.g., an I2C interface. An input of a horizontal synchronization pulse detector 2462 is coupled to an output of the demodulator 2440 and an output of the detector 2462 is coupled to a second input of the digital interface 2426. It should be appreciated that only one of the detectors 2460 and 2462 may be implemented in the receiver 2400. Respective outputs of the interface 2426 are coupled to control inputs of the detectors 2422 and 2428. The AGC engine 2434 is coupled to a port of the digital interface 2426 and receives an indication of whether a received channel is either an analog or digital channel or either a cable or terrestrial channel via the interface 2426. The AGC engine 2434 also controls, via the interface 2426, trip point settings for the detectors 2428 and 2422 based on the ascertained channel type. For desired analog TV channels, the SNR requirements are rather stringent (e.g., 55 dB) and the receiver cannot typically tolerate large attenuation in the front-end. For desired digital TV channels, the SNR is relaxed (e.g., 15 to 20 dB) allowing significant attenuation in the receiver front-end to improve linearity. When employed, an analog channel detector may be placed after the filter 2420 in order to reject adjacent blockers. The AGC trip points may then be adjusted based on an analog or digital desired channel.

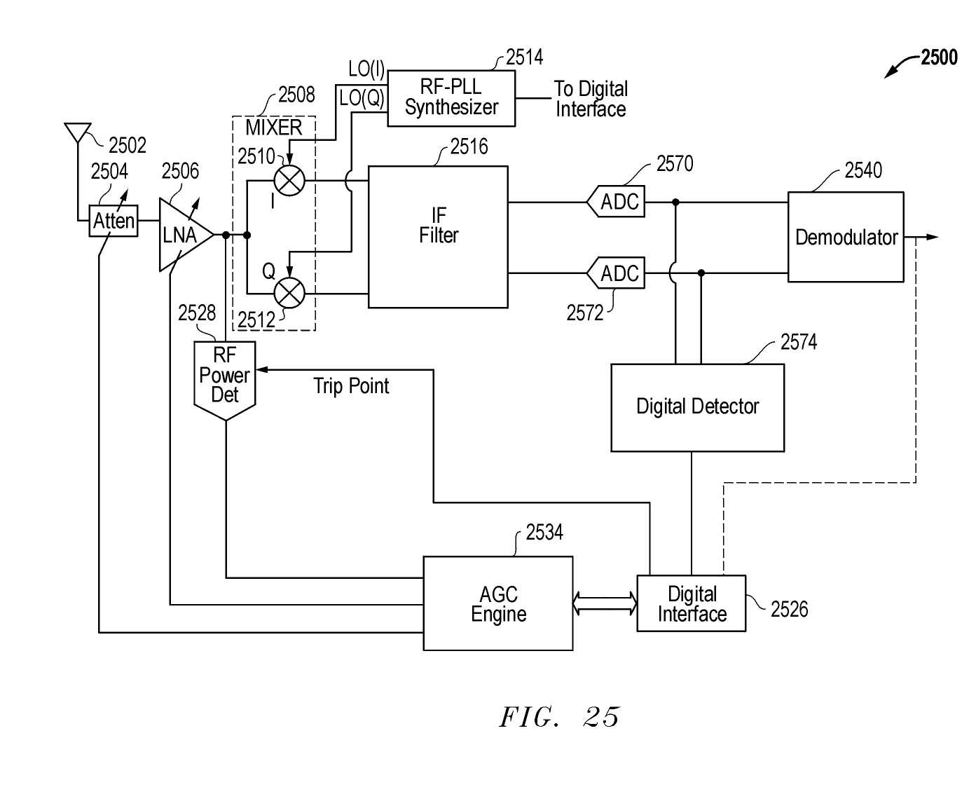

Assuming a hybrid TV receiver has ADCs implemented in an IF path of the receiver, digital signal processing may be readily employed to determine a channel type. For example, as noted above, if the channel power is relatively constant, a digital channel is indicated. In contrast, if high power visual and sound carriers are visible in the signal, an analog channel type is indicated. With reference to FIG. 25, an RF receiver 2500, e.g., a hybrid TV receiver, that employs digital sensing of a channel type is illustrated. The receiver 2500 receives an RF input signal via an antenna 2502. The antenna 2502 is coupled to an input of a variable RF attenuator 2504, whose output is coupled to an input of a variable gain low noise amplifier (LNA) 2506. An output of the LNA 2506 is coupled to an input of mixer 2508, which in the illustrated case includes quadrature mixers 2510 and 2512, which may be mixing DACs. The quadrature mixers 2510 and 2512 receive quadrature local oscillator (LO) signals from an RF-PLL synthesizer 2514, which may be a direct digital frequency synthesizer (DDFS). An input of RF power detector 2528 is coupled to the input of the mixer 2508 and an output of the RF power detector 2528 is coupled to a first input of an AGC control circuit (AGC engine) 2534, such as a digital state machine (DSM), that sets a gain of the LNA 2506 and an attenuation level of the attenuator 2504 responsive to the RF power detector 2528. Outputs of the mixer 2508 are coupled to inputs of an IF filter 2516, which may provide gain (responsive to, for example, the AGC engine 2534) as well as filtering.

The filter 2516 may be, for example, a passive or an active fifth-order polyphase filter (PPF). Respective outputs of the filter 2516 are coupled to respective inputs of ADCs 2570 and 2572. An output of the ADC 2570 is coupled to a first input of a demodulator 2540 and an output of the ADC 2572 is coupled to a second input of the demodulator 2540. A first input of a digital detector 2574 is coupled to the output of the ADC 2570 and a second input of the digital detector 2574 is coupled to the output of the ADC 2572. An output of the digital detector 2574 is coupled to an input of digital interface 2526. The AGC engine 2534 provides control signals to control inputs of the attenuator 2504 and the LNA 2506 based on signals received, via the interface 2526, from the digital detector 2574 or the demodulator 2540.

In general, channel type detection may be readily implemented using digital sensing as most digital demodulators are configured to perform discrete Fourier transform (DFT) channel analysis. In this case, a channel having a relatively constant power level is classified as a digital channel and a channel with relatively high power visual and sound carriers is classified as an analog channel. To speed up channel type determination, the digital detector 2574 may be implemented, at an input of the demodulator 2540. In this case, as noted above, an output of the digital detector 2574 is coupled to an input of the interface 2526, e.g., an I2C interface. The interface 2526 provides a signal to an AGC engine 2534, e.g., a DSM, which, responsive to the signal, sets an appropriate RF AGC trip point for an RF power detector 2528, via the interface 2526. In this case, a channel type may be determined without first requiring the demodulator 2540 to lock. When the determination of channel type is made at the output of the demodulator 2540, the demodulator 2540 must first lock before channel type can be determined. In this case, determination of a channel type is delayed, which may lead to increased distortion in the signal path of the receiver 2500. In the event that the demodulator 2540 is utilized to determine a channel type, the demodulator 2540 may be coupled to the AGC engine 2534 via the interface 2526. The digital detector 2574 may be, for example, a peak-to-average power ratio (PAR) detector. In general, analog TV channels have a relatively low PAR (e.g., around 3 dB), while digital channels have a relatively high PAR (e.g., around 6 to 7 dB for the U.S. NTSC digital standard and as high as 9 to 10 dB for the European DVB-T digital TV standard). In a typical case, to maintain confidence in the channel type determination based on PAR, the PAR calculation should have an accuracy of about 1 dB. Digital circuitry to calculate PAR, having a relatively small area, can be readily implemented having an accuracy of about 1 dB. Setting the AGC trip point based on the received signal PAR usually only makes sense for back-end AGC loops where the power level is dominated by the desired channel and the receiver can determine the signal type. In general, a receiver cannot determine the signal type for blockers. As such, the PAR cannot typically be used to set the AGC trip point level for the RF AGC loop, where the power may be dominated by an unknown blocker.

Accordingly, frequency management techniques have been disclosed herein that move the DDFS clock signal frequency of an RF receiver such that both additive and multiplicative spurs substantially fall out-of-band. Swapping of high-side/low-side mixing may be employed to move a spur out of an IF band of an RF receiver or to select a lower power spur. A hybrid series-shunt regulator may be employed to power a digital block to maintain current impulses on-chip and, thereby, minimize the area of an aggressor magnetic loop. The resonance of the digital block power supply lines may also be adjusted to move the resonance frequency of the power supply lines away from the DDFS generated spurs. Multiple regulators may be employed on sensitive analog circuits to reduce the impact of magnetically coupled spurs from the digital block. Relatively large bypass capacitors may also be implemented to move the victim supply line resonance frequencies away from major DDFS spurs. A guard ring may also be employed within an integrated circuit (IC) to reduce power supply injected spurs. In one or more embodiments, an IC may employ guard rings, substrate ties, a relatively wide high resistivity ring and a stacked N-type well/deep N-type well wall on the aggressor side and a second relatively wide high resistivity ring on the victim side. Substrate noise coupling may also be reduced by connecting the isolation deep N-type well rings directly to an unregulated power supply, both on the aggressor and the victim sides. In general, coupled spurs are attenuated by the reverse PSRR of the digital block hybrid series-shunt regulator and by the forward PSSR of the power supply series regulator(s) used by the analog circuits. One or more AGC trip points of an RF receiver may be adjusted to provide an appropriate boundary between noise limited performance and distortion limited performance. One or more AGC trip points of a hybrid RF receiver may also be adjusted based on whether the receiver is operating in a digital mode or an analog mode.

The above-disclosed subject matter is to be considered illustrative, and not restrictive, and the appended claims are intended to cover all such modifications, enhancements, and other embodiments that fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A receiver, comprising:
a mixing digital-to-analog converter (DAC), comprising:
a radio frequency (RF) transconductance section having an input configured to receive an RF input signal and an output configured to provide an RF current signal; and
a switching section coupled to the RF transconductance section, the switching section having inputs configured to receive bits associated with a digital local oscillator (LO) signal and having an output, wherein the switching section is configured to mix the RF current signal with the digital LO signal to provide an output signal at the output of the switching section, and wherein the output signal is located in a first frequency band;
a direct digital frequency synthesizer (DDFS) having outputs configured to provide the bits associated with the digital LO signal and having a first clock input configured to receive a first clock signal that sets a sample rate for the digital LO signal;
a first power detector having an input coupled to an output of the switching section, wherein an output of the first power detector is configured to provide a channel power associated with the output signal; and
a first control circuit coupled to the output of the first power detector, wherein the first control circuit is configured to identify blockers based on the channel power associated with the output signal and select a frequency of the first clock signal to reduce multiplicative spur frequency translation of the blockers into the first frequency band when a desired channel is selected.

2. The receiver of claim 1, further comprising:
a memory coupled to the first control circuit, wherein the memory is configured to store multiple associated channel power and channel frequency pairs that are utilized by the first control circuit to identify the blockers associated with the desired channel.

3. The receiver of claim 2, wherein the memory is further configured to store multiple frequencies for the first clock signal that do not have associated additive spurs that fall in the first frequency band, and wherein the first control circuit utilizes the multiple frequencies when selecting the frequency of the first clock signal.

4. The receiver of claim 1, further comprising:
a surface acoustic wave filter coupled between the output of the switching section and the input of the first power detector.

5. The receiver of claim 1, further comprising:
a second power detector having a power input, an output, and a control input, wherein the power input of the second power detector is coupled to the input of the RF transconductance section and the output of the second power detector is coupled to the first control circuit, and wherein the first control circuit is configured to adjust a level of a control signal provided to the control input of the second power detector based on whether the blockers are located at sensitive distortion positions for a desired channel.

6. The receiver of claim 1, further comprising:
a second control circuit configured to characterize a frequency spectrum of the receiver;
a look-up table coupled between the first control circuit and the second control circuit, wherein the look-up table is configured to store multiple AGC loop trip points; and
a second power detector having a power input, an output, and a control input, wherein the power input of the second power detector is coupled to the input of the RF transconductance section and the output of the second power detector is coupled to the first control circuit, and wherein the first control circuit is configured to select and provide one of the AGC loop trip points to the control input of the second power detector based on whether the blockers are located at sensitive distortion positions for the desired channel.

7. The receiver of claim 6, wherein the selected one of the AGC loop trip points has a first level when the blockers are located at sensitive distortion positions for the desired channel, and wherein the selected one of the AGC trip points has a second level, that is greater than the first level, when the blockers are not located at sensitive distortion positions for the desired channel.

8. A receiver, comprising:
a mixing digital-to-analog converter (DAC), comprising:
a radio frequency (RF) transconductance section having an input configured to receive an RF input signal and an output configured to provide an RF current signal; and
a switching section coupled to the RF transconductance section, the switching section having inputs configured to receive bits associated with a digital local oscillator (LO) signal and having an output, wherein the switching section is configured to mix the RF current signal with the digital LO signal to provide an output signal at the output of the switching section, and wherein the output signal is located in a first frequency band;
a direct digital frequency synthesizer (DDFS) having outputs configured to provide the bits associated with the digital LO signal and having a first clock input configured to receive a first clock signal that sets a sample rate for the digital LO signal;
a first power detector having a power input, an output and a control input, wherein the power input of the first power detector is coupled to the input of the RF transconductance section; and
a first control circuit coupled to the output of the first power detector, wherein the first control circuit is configured to adjust a level of a control signal provided to the control input of the first power detector based on whether blockers are located at sensitive distortion positions when a desired channel is selected, and wherein the first control circuit is configured to cause the RF input signal to be attenuated when RF power detected by the first power detector exceeds a power level set by the control signal provided to the control input of the first power detector.

9. The receiver of claim 8, further comprising:
a second power detector having a power input, an output, and a control input, wherein the power input of the second power detector is coupled to the output of the switching section and the output of the second power detector is coupled to the first control circuit, wherein the first control circuit is configured to adjust a level of a control signal provided to the control input of the second power detector based on whether the blockers are located at sensitive distortion positions for the desired channel, and wherein the first control circuit is configured to reduce a gain in an IF path of the receiver when IF power detected by the second power detector exceeds a power level set by the control signal provided to the control input of the second power detector.

10. The receiver of claim 8, further comprising:
an analog channel power detector having an input, an output, and a control input, wherein the input of the analog channel power detector is coupled to the output of the switching section and the output of the analog channel power detector is coupled to the first control circuit, wherein the first control circuit is configured to determine whether the receiver is operating in an analog or a digital mode based on an output power indicated at the output of the analog power detector, and wherein the first control circuit is configured to adjust the level of the control signal provided to the control input of the first power detector based on whether the receiver is operating in the analog mode or the digital mode.

11. The receiver of claim 9, further comprising:
a synchronization pulse power detector having an input, an output, and a control input, wherein the input of the synchronization pulse power detector is coupled to the output of the switching section and the output of the synchronization pulse power detector is coupled to the first control circuit, wherein the first control circuit is configured to determine whether the receiver is operating in an analog or a digital mode based on an output power indicated at the output of the synchronization pulse power detector, and wherein the first control circuit is configured to adjust the level of the control signal provided to the control input of the first power detector based on whether the signal is operating in the analog mode or the digital mode.

12. The receiver of claim 8, further comprising:
a digital power detector having an input, an output, and a control input, wherein the input of the digital power detector is coupled to the output of the switching section and the output of the digital power detector is coupled to the first control circuit, wherein the first control circuit is configured to determine whether the receiver is operating in an analog or a digital mode based on an output power indicated at the output of the digital power detector.

13. A method of improving reception of a receiver, comprising:
identifying one or more blockers associated with a desired channel, included in a radio frequency (RF) input signal, based on a channel power associated with an output signal of the receiver, wherein the output signal is located in a first frequency band; and
selecting a frequency of a clock signal provided to a direct digital frequency synthesizer (DDFS) to reduce multiplicative spur frequency translation of the one or more blockers into the first frequency band when a digital local oscillator (LO) signal provided by the DDFS is mixed with the RF input signal, wherein the clock signal sets a sample rate for the digital LO signal.

14. The method of claim 13, wherein the selecting further comprises:
selecting the frequency of the clock signal to reduce additive spurs in the first frequency band.

15. The method of claim 13, further comprising:
setting a first automatic gain control (AGC) loop power detector trip point of a first AGC loop associated with an RF path of the receiver to a first level that substantially avoids signal clipping in the RF path when the one or more blockers are not located at sensitive distortion positions for the desired channel; and
setting the first AGC loop power detector trip point to a second level to reduce distortion products that increase with blocker power when the one or more blockers are located at the sensitive distortion positions for the desired channel, wherein the second level is lower in magnitude than the first level.

16. The method of claim 15, further comprising:
attenuating the RF input signal when an RF power, associated with the RF input signal, exceeds a power level associated with the second level.

17. The method of claim 15, further comprising:
setting a second AGC loop power detector trip point of a second AGC loop associated with an intermediate frequency (IF) path of the receiver to a third level that substantially avoids signal clipping in the IF path; and
reducing a gain in the IF path when IF power associated with the IF path exceeds a power level associated with the third level.

18. The method of claim 13, wherein the first frequency band is an intermediate frequency (IF) band.

19. A method of improving reception of a hybrid receiver, comprising:
determining whether a received channel, included within a radio frequency (RF) input signal of the hybrid receiver, is an analog channel or a digital channel;
setting a first automatic gain control (AGC) loop power detector trip point of a first AGC loop associated with an RF path of the hybrid receiver to a first level when the received channel is an analog channel; and
setting the first AGC loop power detector trip point to a second level when the received channel is a digital channel, wherein the second level is lower in magnitude than the first level.

20. The method of claim 19, further comprising:
setting a second AGC loop power detector trip point of a second AGC loop associated with an intermediate frequency (IF) path of the hybrid receiver to a third level that substantially avoids signal clipping in the IF path; and
reducing a gain in the IF path when IF power associated with the IF path exceeds a power level associated with the third level.
